(19) United States
(12) Patent Application Publication
(10) Pub. No.: US 2023/0282667 A1
(43) Pub. Date: Sep. 7, 2023

(54) IMAGE SENSOR

(71) Applicant: SAMSUNG ELECTRONICS CO., LTD., Suwon-si (KR)

(72) Inventor: Iljoong KIM, Gunpo-si (KR)

(73) Assignee: SAMSUNG ELECTRONICS CO., LTD., Suwon-si (KR)

(21) Appl. No.: 18/103,894

(22) Filed: Jan. 31, 2023

(30) Foreign Application Priority Data
Mar. 4, 2022 (KR) 10-2022-0028168
Apr. 28, 2022 (KR) 10-2022-0053099

(51) Int. Cl. H01L 27/146

(52) U.S. Cl. CPC H01L 27/14636; H01L 27/1463; H01L 27/14643

(57) ABSTRACT

Disclosed is an image sensor comprising a first substrate including unit pixel regions and having first and second surfaces opposite to each other, a second substrate below the first surface of the first substrate, a third substrate below the second substrate, a lower dielectric layer between the second and third substrates, a lower wiring line in the lower dielectric layer, an intermediate dielectric layer between the first and second substrates, a first bonding pad in the intermediate dielectric layer, a connection contact that penetrates the second substrate and electrically connects the lower wiring line to the first bonding pad, and a contact pattern in the intermediate dielectric layer and below the first bonding pad. The first bonding pad is vertically spaced apart from the connection contact by the contact pattern.

### CROSS-REFERENCE TO RELATED APPLICATIONS

This application is based on and claims priority under 35 U.S.C § 119 to Korean Patent Applications No. 10-2022-0028168 filed on Mar. 4, 2022 and No. 10-2022-0053099 filed on Apr. 28, 2022 in the Korean Intellectual Property Office, the disclosures of which are hereby incorporated by reference in their entirety.

### BACKGROUND

### 1. Field

The disclosure relate to an image sensor, and more particularly, to a complementary metal oxide semiconductor (CMOS) image sensor.

### 2. Description of Related Art

An image sensor converts optical images into electrical signals. An image sensor can be classified into a charge coupled device (CCD) type and a complementary metal oxide semiconductor (CMOS) type. A CMOS type image sensor is abbreviated to CIS (CMOS image sensor). The CIS includes a plurality of unit pixel regions that are arranged two-dimensionally. Each of the unit pixel regions includes a photodiode. The photodiode serves to convert incident light into electrical signals.

### SUMMARY

One or more aspects of the disclosure provide an image sensor having improved electrical properties.

According to an aspect of the disclosure, there is provided an image sensor including: a first substrate including unit pixel regions, the first substrate having a first surface and a second surface on an opposite side of the first surface; a second substrate provided below the first surface of the first substrate; a third substrate provided below the second substrate; a lower dielectric layer provided between the second substrate and the third substrate; a lower wiring line provided in the lower dielectric layer; an intermediate dielectric layer provided between the first substrate and the second substrate; a first bonding pad provided in the intermediate dielectric layer; a connection contact configured to penetrate the second substrate and electrically connect the lower wiring line to the first bonding pad; and a contact pattern provided in the intermediate dielectric layer and below the first bonding pad, wherein the first bonding pad is spaced apart from the connection contact by the contact pattern.

According to another aspect of the disclosure, there is provided an image sensor, including: a first substrate including unit pixel regions; a second substrate provided below the first substrate; a third substrate provided below the second substrate; a first wiring layer and a second wiring layer provided between the first substrate and the second substrate, the first wiring layer being closer than the second wiring layer to the first substrate; a third wiring layer provided between the second substrate and third substrate; and a connection contact configured to penetrate the second substrate and electrically connect the second wiring layer to the third wiring layer, wherein the second wiring layer includes: a first bonding pad provided adjacent to the first wiring layer; and a contact pattern provided between the first bonding pad and the connection contact, wherein the contact pattern includes a recess region that is recessed in a direction toward the second substrate from a top surface of the contact pattern, wherein the first bonding pad includes: a line part that extends in a first direction; and a protrusion part that protrudes from the line part into the recess region of the contact pattern in the direction toward the second substrate.

According to another aspect of the disclosure, there is provided an image sensor, including: a first substrate having a first surface and a second surface on an opposite side of the first surface; a pixel isolation pattern provided in the first substrate, the pixel isolation pattern defining unit pixel regions, and the pixel isolation pattern including a first isolation pattern and a second isolation pattern that is between the first isolation pattern and the first substrate; a photoelectric conversion region provided in each of the unit pixel regions; a floating diffusion region provided in each of the unit pixel regions and adjacent to the first surface of the first substrate; a transfer gate provided on the first surface of the first substrate; a first wiring layer configured to cover the transfer gate, the first wiring layer including an upper dielectric layer, an upper wiring line provided in the upper dielectric layer, and a first bonding pad provided in the upper dielectric layer; a second substrate provided below the first wiring layer; a gate electrode provided on the second substrate; a source region provided in the second substrate on a first side of the gate electrode and a drain region provided in the second substrate on a second side of the gate electrode; a second wiring layer provided between the second substrate and the first wiring layer, the second wiring layer comprising an intermediate dielectric layer and a second bonding pad in the intermediate dielectric layer, the second bonding pad being in contact with the first bonding pad; a third substrate provided below the second substrate; a logic transistor provided on the third substrate; a third wiring layer provided between the second substrate and the third substrate, the third wiring layer including a lower dielectric layer and a lower wiring line in the lower dielectric layer; a connection contact configured to penetrate the second substrate and electrically connects the lower wiring line to the second bonding pad; a contact pattern provided in the intermediate dielectric layer and between the second bonding pad and the connection contact; a color filter provided on the second surface of the first substrate; and a microlens part provided on the color filter, wherein the first bonding pad is spaced apart from the connection contact by the contact pattern.

According to another aspect of the disclosure, there is provided an apparatus including: a first substrate, a second substrate and a third substrate, the second substrate being provided between the first substrate and the third substrate; a first dielectric layer provided between the second substrate and the third substrate; a wiring line provided in the first dielectric layer; a second dielectric layer provided between the first substrate and the second substrate; a bonding pad provided in the second dielectric layer; a connection contact provided in the second substrate and configured to electrically connect the wiring line to the bonding pad; and a contact pattern provided in the second dielectric layer between the bonding pad and the connection contact.

### BRIEF DESCRIPTION OF THE DRAWINGS

FIG. 1 illustrates a circuit diagram showing an image sensor according to an example embodiment of the disclosure.

FIG. 2 illustrates a plan view showing an image sensor according to an example embodiment of the disclosure.

FIG. 3 illustrates a cross-sectional view taken along line A-A′ of FIG. 2.

FIG. 4 illustrates an enlarged plan view showing section M depicted in FIG. 2.

FIG. 5 illustrates a cross-sectional view taken along line B-B′ of FIG. 4.

FIG. 6 illustrates an enlarged cross-sectional view showing section N depicted in FIG. 5.

FIG. 7 illustrates an enlarged cross-sectional view of section N depicted in FIG. 5, showing an image sensor according to a comparative example.

FIGS. 8A to 8G illustrate cross-sectional views showing a method of fabricating an image sensor according to an example embodiment of the disclosure.

FIGS. 9A to 9C illustrate cross-sectional views taken along line B-B′ of FIG. 4, showing an image sensor according to an example embodiment of the disclosure.

FIG. 10 illustrates a cross-sectional view showing an image sensor according to an example embodiment of the disclosure.

FIG. 11 illustrates a cross-sectional view taken along line B-B′ of FIG. 4, showing an image sensor according to an example embodiment of the disclosure.

FIG. 12 illustrates an enlarged cross-sectional view showing section N depicted in FIG. 11.

FIGS. 13A and 13B illustrate cross-sectional views showing a method of fabricating an image sensor according to an example embodiment of the disclosure.

### DETAIL DESCRIPTION

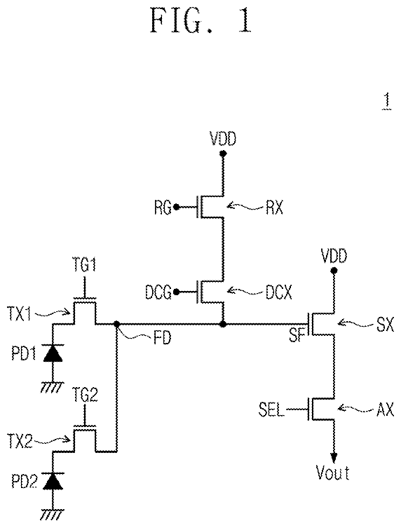

FIG. 1 illustrates a circuit diagram showing an image sensor according to an example embodiment of the disclosure.

Referring to FIG. 1, an image sensor 1 may include unit pixel regions each including photodiodes PD1 and PD2, a transfer transistor TX, a source follower transistor SX, a reset transistor RX, a dual conversion transistor DCX, and a selection transistor AX. The transfer transistor TX, the source follower transistor SX, the reset transistor RX, the dual conversion transistor DCX, and the selection transistor AX may respectively include a transfer gate TG, a source follower gate SF, a reset gate RG, a dual conversion gate DCG, and a selection gate SEL. According to an example embodiment, each of the photodiodes PD1 and PD2 include a respective transfer transistor TX. For example, the photodiode PD1 may be connected to a transfer transistor TX1 having a transfer gate TG1 and the photodiode PD2 may be connected to a transfer transistor TX2 having a transfer gate TG2.

The photodiodes PD1 and PD2 may each include an n-type impurity region and a p-type impurity region. A floating diffusion region FD may serve as a drain of the transfer transistor TX. The floating diffusion region FD may serve as a source of the dual conversion transistor DCX. The floating diffusion region FD may be electrically connected to the source follower gate SF of the source follower transistor SX. The source follower transistor SX may be connected to the selection transistor AX.

An operation of the image sensor 1 will be explained below with reference to FIG. 1. According to an example embodiment, a power voltage VDD may be applied to a drain of the reset transistor RX and a drain of the source follower transistor SX under a light-blocked state, such that the reset transistor RX and the dual conversion transistor DCX may be turned on to discharge charges that remain on the floating diffusion region FD. Thereafter, when the reset transistor RX is turned off and external light is incident on the photodiodes PD1 and PD2, electron-hole pairs may be generated from each of the photodiodes PD1 and PD2. Holes may be transferred to and accumulated on p-type impurity regions of the photodiodes PD1 and PD2, and electrons may be transferred to and accumulated on n-type impurity regions of the photodiodes PD1 and PD2. When the transfer transistor TX is turned on, charges such as electrons and holes may be transferred to and accumulated on the floating diffusion region FD. A gate bias of the source follower transistor SX may change in proportion to an amount of the accumulated charges, and this may bring about a variation in source potential of the source follower transistor SX. In this case, when the selection transistor AX is turned on, signals by charges may be read out transmitted through a column line.

A wiring line may be electrically connected to at least one selected from the transfer gate TG1, the transfer gate TG2, the source follower gate SF, the dual conversion gate DCG, the reset gate RG, and the selection gate SEL. The wiring line may be configured to apply the power voltage VDD to the drain of the reset transistor RX or the drain of the source follower transistor SX. The wiring line may include the column line connected to the selection transistor AX. The wiring line may be wirings discussed below.

FIG. 1 illustrates an example embodiment of a structure in which the photodiodes PD1 and PD2 are connected to one floating diffusion region FD, but the disclosure are not limited thereto. For example, one unit pixel region may include one of the photodiodes PD1 and PD2, the floating diffusion region FD, and four transistors TX, RX, AX, and SX, and neighboring unit pixel regions may share one of the reset transistor RX, the source follower transistor SX, and the selection transistor AX. In addition, there is no limitation imposed on the number of the photodiodes PD1 and PD2 that electrically share one floating diffusion region FD. As such, according to another example embodiment, more than two photodiodes may be provided to electrically share one floating diffusion region FD. Therefore, the image sensor may increase in integration.

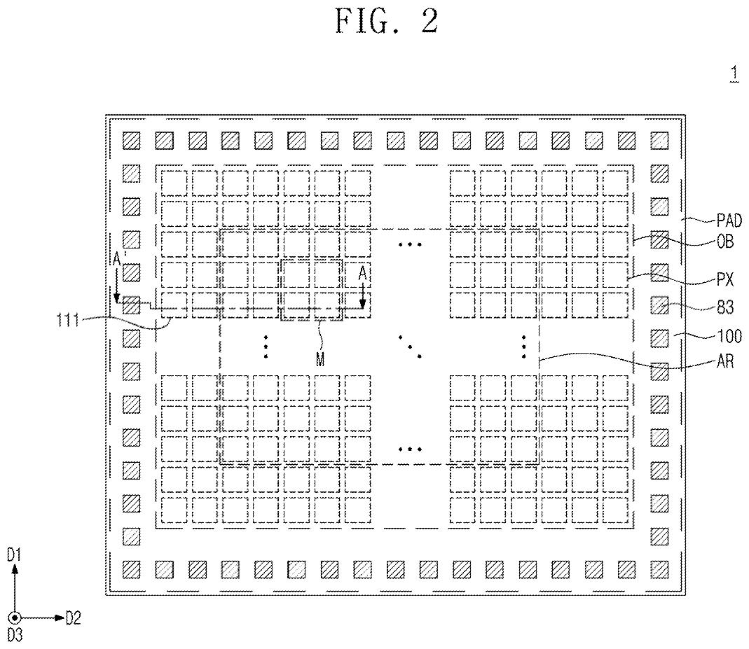

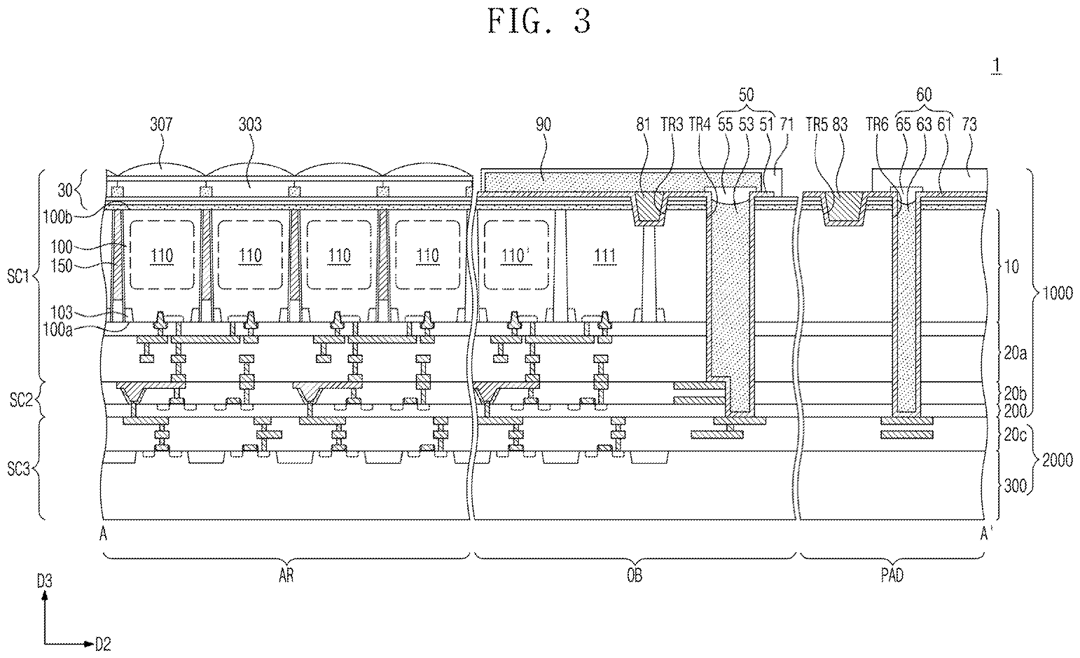

FIG. 2 illustrates a plan view showing an image sensor according to an example embodiment of the disclosure. FIG. 3 illustrates a cross-sectional view taken along line A-A′ of FIG. 2.

Referring to FIGS. 2 and 3, an image sensor 1 may include a sensor chip 1000 and a logic chip 2000. The sensor chip 1000 may include a first semiconductor chip SC1 and a second semiconductor chip SC2. The logic chip 2000 may include a third semiconductor chip SC3. The first semiconductor chip SC1 may include a photoelectric conversion layer 10, a first wiring layer 20a, and an optical transmission layer 30. The photoelectric conversion layer 10 may include a first substrate 100, a pixel isolation pattern 150, a first device isolation pattern 103, and photoelectric conversion regions 110 provided in the first substrate 100. According to an example embodiment, external light that is incident on the image sensor 1 may be converted into electrical signals in the photoelectric conversion regions 110.

When viewed in plan, the first substrate 100 may include a pixel array area AR, an optical black area OB, and a pad area PAD. When viewed in plan, the pixel array area AR may be provided on a central portion of the first substrate 100. The pixel array area AR may include a plurality of unit pixel regions PX. The unit pixel regions PX may output photoelectric signals from incident light. The unit pixel regions PX may be two-dimensionally arranged in columns and rows. The columns may be parallel to a first direction D1. The rows may be parallel to a second direction D2. In this description, the first direction D1 may be parallel to a first surface 100a of the first substrate 100. The second direction D2 may be parallel to the first surface 100a of the first substrate 100 and may intersect the first direction D1. A third direction D3 may be substantially perpendicular to the first surface 100a of the first substrate 100.

The pad area PAD may be provided on an edge portion of the first substrate 100, and when viewed in plan, may surround the pixel array area AR. Second pad terminals 83 may be provided on the pad area PAD. The second pad terminals 83 may externally output electrical signals generated from the unit pixel regions PX. Alternatively, external electrical signals or voltages may be transferred through the second pad terminals 83 to the unit pixel regions PX. As the pad area PAD is provided on the edge portion of the first substrate 100, the second pad terminals 83 may be easily coupled to outside.

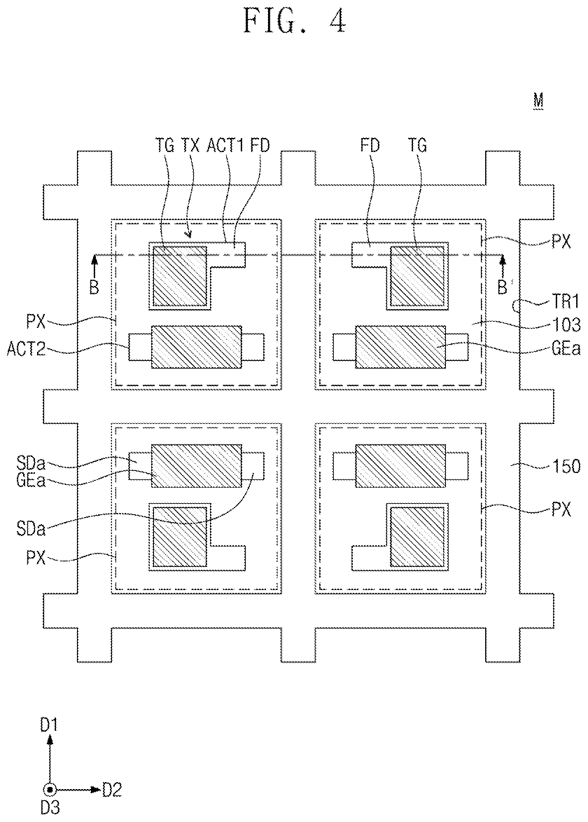

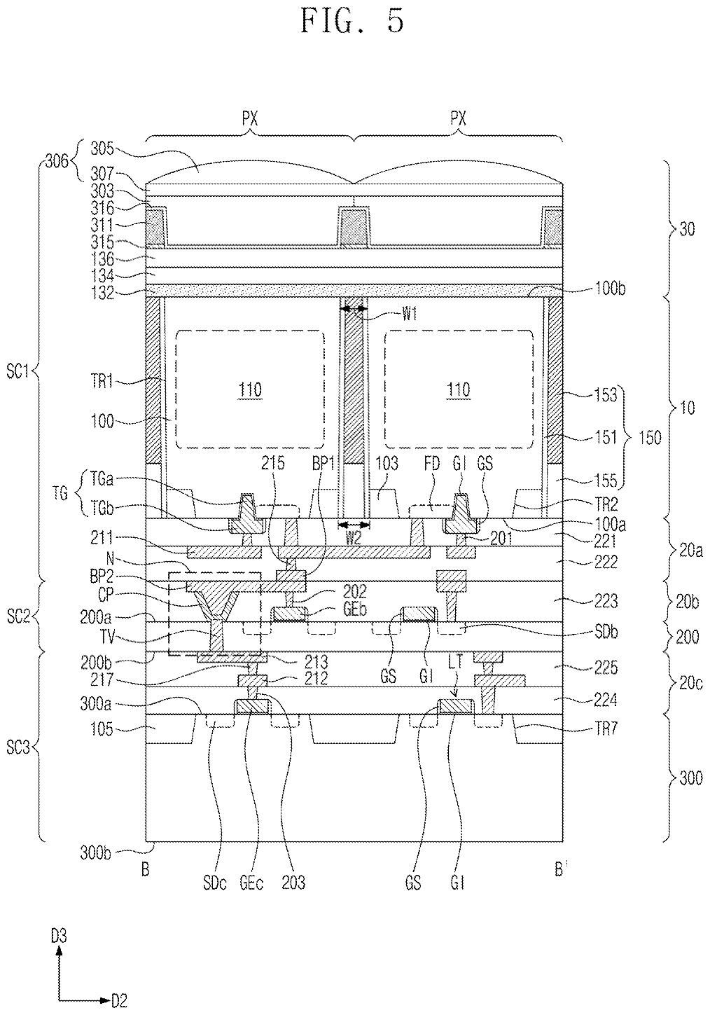

The optical black area OB may be provided between the pad area PAD and the pixel array area AR of the first substrate 100. When viewed in plan, the optical black area OB may surround the pixel array area AR. The optical black area OB may include a plurality of dummy regions 111. The dummy region 111 may generate signals that are used as information to remove subsequent process noise. The pixel array area AR of the image sensor will be further discussed in detail below with reference to FIGS. 4 and 5.

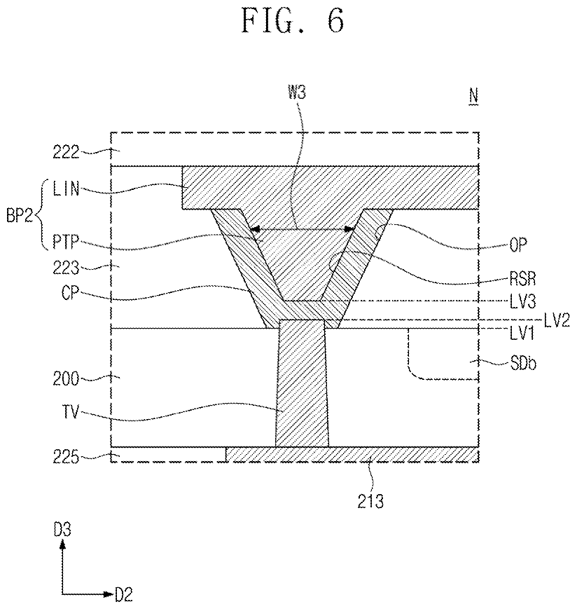

FIG. 4 illustrates an enlarged plan view showing section M depicted in FIG. 2. FIG. 5 illustrates a cross-sectional view taken along line B-B′ of FIG. 4. FIG. 6 illustrates an enlarged cross-sectional view showing section N depicted in FIG. 5.

Referring to FIGS. 4 and 5, an image sensor may include a third semiconductor chip SC3, a second semiconductor chip SC2, and a first semiconductor chip SC1 that are sequentially stacked in a third direction D3. The first semiconductor chip SC1 may include a photoelectric conversion layer 10, a first gate electrode GEa (FIG. 4), a transfer gate TG, a first wiring layer 20a, and an optical transmission layer 30. The photoelectric conversion layer 10 may include a first substrate 100, a pixel isolation pattern 150, and a first device isolation pattern 103 (FIG. 4).

The first substrate 100 may have a first surface 100a and a second surface 100b that are opposite to each other. A light ray may be incident on the second surface 100b of the first substrate 100. The first wiring layer 20a may be provided on the first surface 100a of the first substrate 100, and the optical transmission layer 30 may be provided on the second surface 100b of the first substrate 100. The first substrate 100 may be a silicon substrate or a silicon-on-insulator (SOI) substrate. For example, the first substrate 100 may include a silicon substrate, a germanium substrate, or a silicon-germanium substrate. The first substrate 100 may include first conductivity type impurities. For example, the first conductivity type impurities may include p-type impurities, such as one or more of aluminum (Al), boron (B), indium (In), and gallium (Ga).

The first substrate 100 may include a plurality of unit pixel regions PX defined by the pixel isolation pattern 150. The plurality of unit pixel regions PX may be arranged in a matrix shape along first and second directions D1 and D2 that intersect each other. The first substrate 100 may include photoelectric conversion regions 110. In the first substrate 100, the photoelectric conversion regions 110 may be provided on corresponding unit pixel regions PX. The photoelectric conversion regions 110 may have their functions and roles the same as those of the photodiodes PD1 and PD2 of FIG. 1.

The photoelectric conversion regions 110 may be zones where second conductivity type impurities are doped into the first substrate 100. The second conductivity type impurities may have a conductivity type opposite to that of the first conductivity type impurities. The second conductivity type impurities may include n-type impurities, such as one or more of phosphorus, arsenic, bismuth, and antimony. Each of the photoelectric conversion regions 110 may include a first section adjacent to the first surface 100a and a second section adjacent to the second surface 100b. The photoelectric conversion region 110 may have a difference in impurity concentration between the first section and the second section. Therefore, the photoelectric conversion region 110 may have a potential slope between the first and second surfaces 100a and 100b of the first substrate 100.

The first substrate 100 and the photoelectric conversion region 110 may constitute a photodiode. For example, a photodiode may be constituted by a p-n junction between the first substrate 100 having the first conductivity type and the photoelectric conversion region 110 having the second conductivity type. The photoelectric conversion region 110 which constitutes the photodiode may generate and accumulate photo-charges in proportion to intensity of incident light.

The pixel isolation pattern 150 may be provided in the first substrate 100, defining the unit pixel regions PX. For example, the pixel isolation pattern 150 may be provided between the unit pixel regions PX of the first substrate 100. When viewed in plan, the pixel isolation pattern 150 may have a grid structure. When viewed in plan, the pixel isolation pattern 150 may completely surround each of the unit pixel regions PX. The pixel isolation pattern 150 may be provided in a first trench TR1. The first trench TR1 may be recessed from the first surface 100a of the first substrate 100. The pixel isolation pattern 150 may extend from the first surface 100a toward the second surface 100b of the first substrate 100. The pixel isolation pattern 150 may be a deep trench isolation (DTI) layer. The pixel isolation pattern 150 may penetrate the first substrate 100. The pixel isolation pattern 150 may have a vertical height substantially the same as a vertical thickness of the first substrate 100. For example, the pixel isolation pattern 150 may have a width which gradually decreases in a direction from the first surface 100a toward the second surface 100b of the first substrate 100. A first width W1 may be given as a width at the first surface 100a of the pixel isolation pattern 150, and a second width W2 may be given as a width at the second surface 100b of the pixel isolation pattern 150. For example, the first width W1 may be greater than the second width W2.

The pixel isolation pattern 150 may include a first isolation pattern 151, a second isolation pattern 153, and a capping pattern 155. The first isolation pattern 151 may be provided along a sidewall of the first trench TR1. The first isolation pattern 151 may include, for example, one or more of a silicon-based dielectric material (e.g., silicon nitride, silicon oxide, and/or silicon oxynitride) and a high-k dielectric material (e.g., hafnium oxide and/or aluminum oxide). Alternatively, the first isolation pattern 151 may include a plurality of layers, which plurality of layers may include different materials from each other. The first isolation pattern 151 may have a refractive index less than that of the first substrate 100. Accordingly, crosstalk may be prevented or reduced between the unit pixel regions PX of the first substrate 100.

The second isolation pattern 153 may be provided in the first isolation pattern 151. For example, a sidewall of the second isolation pattern 153 may be surrounded by the first isolation pattern 151. The first isolation pattern 151 may be interposed between the second isolation pattern 153 and the first substrate 100. The first isolation pattern 151 may separate the second isolation pattern 153 from the first substrate 100. Therefore, when the image sensor operates, the second isolation pattern 153 may be electrically separated from the first substrate 100. The second isolation pattern 153 may include a crystalline semiconductor material, for example, polysilicon. For example, the second isolation pattern 153 may further include dopants, which dopants may include first conductivity type impurities or second conductivity type impurities. For example, the second isolation pattern 153 may include doped polysilicon. For another example, the second isolation pattern 153 may include undoped crystalline semiconductor material. For example, the second isolation pattern 153 may include undoped polysilicon. The term “undoped” may mean that no doping process is intentionally performed. The dopants may include n-type dopants or p-type dopants.

The capping pattern 155 may be provided on a bottom surface of the second isolation pattern 153. The capping pattern 155 may be provided adjacent to the first surface 100a of the first substrate 100. The capping pattern 155 may have a bottom surface coplanar with the first surface 100a of the first substrate 100. The capping pattern 155 may have a top surface substantially the same as the bottom surface of the second isolation pattern 153. The capping pattern 155 may include a non-conductive material. For example, the capping pattern 155 may include one or more of a silicon-based dielectric material (e.g., silicon nitride, silicon oxide, and/or silicon oxynitride) and a high-k dielectric material (e.g., hafnium oxide and/or aluminum oxide). The pixel isolation pattern 150 may thus prevent photo-charges generated from light incident on each unit pixel region PX from drifting into neighboring unit pixel regions PX. Accordingly, the pixel isolation pattern 150 may prevent crosstalk between the unit pixel regions PX.

The first device isolation pattern 103 may be provided in the first substrate 100. For example, the first device isolation pattern 103 may be provided in a second trench TR2. The second trench TR2 may be recessed from the first surface 100a of the first substrate 100. The first device isolation pattern 103 may be a shallow trench isolation (STI) layer. The first device isolation pattern 103 may define a first active pattern ACT1 and a second active pattern ACT2 (see FIG. 4). A top surface of the first device isolation pattern 103 may be provided in the first substrate 100. The first device isolation pattern 103 may have a width that gradually decreases in a direction from the first surface 100a toward the second surface 100b of the first substrate 100. The top surface of the first device isolation pattern 103 may be vertically spaced apart from the photoelectric conversion regions 110. The pixel isolation pattern 150 may overlap a portion of the first device isolation pattern 103. The pixel isolation pattern 150 may penetrate the first device isolation pattern 103. At least a portion of the first device isolation pattern 103 may be provided on and in contact with a lower sidewall of the pixel isolation pattern 150. A stepwise structure may be constituted by a sidewall of the first device isolation pattern 103, by the top surface of the first device isolation pattern 103 and by a sidewall of the pixel isolation pattern 150. The first device isolation pattern 103 may have a depth less than that of the pixel isolation pattern 150. The first device isolation pattern 103 may include a silicon-based dielectric material. For example, the first device isolation pattern 103 may include one or more of silicon nitride, silicon oxide, and silicon oxynitride. For another example, the first device isolation pattern 103 may include a plurality of layers, which layers may include different materials from each other.

Each of the unit pixel regions PX may include a first active pattern ACT1. According to an example embodiment, the first active pattern may be defined by the first device isolation pattern 103. The first active pattern ACT1 may have an L shape when viewed in plan. Each of the unit pixel regions PX may include the second active pattern ACT2. The second active patterns ACT2 may each have a linear shape that extends in the second direction D2. However, planar shapes of the first and second active patterns ACT1 and ACT2 are not limited to that shown in FIG. 4, but may be variously changed.

The first substrate 100 may be provided on its first surface 100a with a transfer transistor TX, a source follower transistor SX, a reset transistor RX, a dual conversion transistor DCX, and a selection transistor AX that are discussed above with reference to FIG. 1.

The transfer transistor TX may be provided on the first active pattern ACT1. One of the reset transistor RX, the dual conversion transistor DCX, and the selection transistor AX may be provided on the second active pattern ACT2.

The transfer transistor TX may be electrically connected to the photoelectric conversion region 110. The transfer transistor TX may include a transfer gate TG and a floating diffusion region FD. The transfer gate TG may include a second part TGb provided on the first surface 100a of the first substrate 100 and a first part TGa that extend into the first substrate 100 from the second part TGb. A maximum width in the second direction D2 of the second part TGb may be greater than a maximum width in the second direction D2 of the first part TGa. A gate dielectric pattern GI may be interposed between the transfer gate TG and the first substrate 100. The gate dielectric pattern GI may extend along a top surface and sidewalls of the first part TGa. The floating diffusion region FD may be adjacent to one side of the transfer gate TG. The floating diffusion region FD may be positioned in the first active pattern ACT1. The floating diffusion region FD may have the second conductivity type (e.g., n-type) opposite to the first conductivity type of the first substrate 100.

According to an example embodiment, the reset transistor RX, the dual conversion transistor DCX, and the selection transistor AX may be provided on the second active patterns ACT2 of the unit pixel regions PX. The selection transistor AX may include a selection gate SEL. The reset transistor RX may include a reset gate RG, and the dual conversion transistor DCX may include a dual conversion gate DCG. The first gate electrode GEa may be one of the selection gate SEL, the reset gate RG, and the dual conversion gate DCG. A gate spacer GS may be provided on a sidewall of the first gate electrode GEa. The gate spacer GS may include, for example, silicon nitride, silicon carbonitride, or silicon oxynitride. A gate dielectric pattern GI may be interposed between the first gate electrode GEa and the first substrate 100. The first substrate 100 may be provided therein with first source/drain regions SDa. The first source/drain region SDa may be a doped region in the second active pattern ACT2. The first source/drain regions SDa may be provided on opposite sides of the first gate electrode GEa. For example, the first source/drain region SDa may have the second conductivity type (e.g., n-type) opposite to the first conductivity type of the first substrate 100.

The first wiring layer 20a may include upper dielectric layers 221 and 222, upper wiring lines 211, upper vias 215, and upper contacts 201. The upper dielectric layers 221 and 222 may include a first upper dielectric layer 221 and a second upper dielectric layer 222. The first upper dielectric layer 221 may cover the first surface 100a of the first substrate 100. The first upper dielectric layer 221 may cover the transfer gate TG and the first gate electrode GEa. The second upper dielectric layer 222 may be provided on the first upper dielectric layer 221. The first and second upper dielectric layers 221 and 222 may include a non-conductive material. For example, the first and second upper dielectric layers 221 and 222 may include a silicon-based dielectric material, such as one or more of silicon oxide, silicon nitride, and silicon oxynitride.

The upper wiring lines 211 may be provided on the first upper dielectric layer 221. The upper wiring lines 211 may be provided in the second upper dielectric layer 222. The upper wiring lines 211 may be provided in an upper portion of the second upper dielectric layer 222. The second upper dielectric layer 222 may be provided in its lower portion with first bonding pads BP1. The first bonding pads BP1 may have their bottom surfaces exposed by the second upper dielectric layer 222. The upper vias 215 may be provided in the second upper dielectric layer 222. The upper vias 215 may connect the upper wiring lines 211 to the first bonding pads BP1. The upper contacts 201 may penetrate the first upper dielectric layer 221. The upper wiring line 211 may be connected through the upper contact 201 to one of the transfer gate TG, the first gate electrode GEa, and the floating diffusion region FD.

An arrangement of the upper wiring lines 211 may not depend on an arrangement of the photoelectric conversion regions 110, and may be variously changed without being limited to the illustrated in FIG. 5. As such, according to another example embodiment, a different arrangement of the upper wiring lines 211 may be provided. The upper wiring lines 211, the upper vias 215, the upper contacts 201, and the first bonding pads BP1 may include a metallic material. For example, the upper wiring lines 211, the upper vias 215, the upper contacts 201, and the first bonding pads BP1 may include at least one selected from tungsten (W), aluminum (Al), copper (Cu), tungsten nitride (W), tantalum nitride (TaN), and titanium nitride (TiN). The upper wiring lines 211, the upper vias 215, the upper contacts 201, and the first bonding pads BP1 may each include copper, for example.

The optical transmission layer 30 may include color filters 303 and a microlens part 306. The optical transmission layer 30 may condense and filter externally incident light, and the photoelectric conversion layer 10 may receive the focused and filtered light. The color filters 303 may be provided on the second surface 100b of the first substrate 100. The color filters 303 may be provided on corresponding unit pixel regions PX. The color filters 303 may include primary color filters. The color filters 303 may include first, second, and third color filters that have different colors from each other. For example, the first, second, and third color filters may include green, red, and blue color filters. The first, second, and third color filters may be arranged in a Bayer pattern format. For another example, the first, second, and third color filters may include different colors such as cyan, magenta, or yellow.

The optical transmission layer 30 may further include a first fixed charge layer 132, a second fixed charge layer 134, and a planarization layer 136 that are sequentially provided between the color filters 303 and the second surface 100b of the first substrate 100. The first fixed charge layer 132, the second fixed charge layer 134, and the planarization layer 136 may include different materials from each other. For example, the first fixed charge layer 132 may include aluminum oxide, the second fixed charge layer 134 may include hafnium oxide, and the planarization layer 136 may include silicon oxide. The first fixed charge layer 132, the second fixed charge layer 134, and the planarization layer 136 may prevent reflection of light incident on the second surface 100b of the first substrate 100, and thus the incident light may satisfactorily arrive at the photoelectric conversion regions 110.

The microlens part 306 may be provided on the color filters 303. The microlens part 306 may include a planarization section 305 in contact with the color filters 303, and may also include microlenses 307 provided on the planarization section 305 and provided on corresponding unit pixel regions PX. The planarization section 305 may include, for example, an organic material. Alternatively, the planarization section 305 may include silicon oxide or silicon oxynitride. Each of the microlenses 307 may have a convex shape to focus light which is incident on the unit pixel region PX. The microlenses 307 may vertically overlap corresponding photoelectric conversion regions 110.

The optical transmission layer 30 may further include a low-refractive pattern 311, a protection layer 316, and a light-shield pattern 315. The light-shield pattern 315 may be provided on a top surface of the planarization layer 136. The light-shield pattern 315 may vertically overlap the pixel isolation pattern 150. For example, the light-shield pattern 315 may have a grid structure. The light-shield pattern 315 may include, for example, at least one selected from metal, such titanium, tantalum, or tungsten, and metal nitride, such as titanium nitride.

The low-refractive pattern 311 may lie between and separate from each other neighboring color filters 303. The low-refractive pattern 311 may be provided on a top surface of the light-shield pattern 315. The low-refractive pattern 311 may vertically overlap the pixel isolation pattern 150 and the light-shield pattern 315. For example, the low-refractive pattern 311 may have a grid structure. The low-refractive pattern 311 may be formed of a material whose refractive index is less than that of color filters 303. The low-refractive pattern 311 may be formed of an organic material. For example, the low-refractive pattern 311 may be a polymer layer including silica nano-particles. Because the low-refractive pattern 311 has a low refractive index, it may be possible to increase an amount of light that is incident on the photoelectric conversion region 110 and to reduce crosstalk between the unit pixel regions PX. In this configuration, the photoelectric conversion region 110 may increase in light-receiving efficiency and improve in signal-to-noise ratio (SNR) properties.

The protection layer 316 may have a substantially uniform thickness that covers a surface of the low-refractive pattern 311. The protection layer 316 may further extend onto a top surface of each of the color filters 303. The protection layer 316 may include, for example, a single or multiple layer including at least one selected from an aluminum oxide layer and a silicon carbide layer. The protection layer 316 may serve to protect the color filters 303 and to absorb moisture.

The second semiconductor chip SC2 may be electrically connected to the first semiconductor chip SC1. The second semiconductor chip SC2 may be adjacent to the first surface 100a of the first substrate 100. The second semiconductor chip SC2 may include a second substrate 200 and a second wiring layer 20b.

The second substrate 200 may have a third surface 200a and a fourth surface 200b that are opposite to each other. The second wiring layer 20b may be provided on the third surface 200a of the second substrate 200. The second wiring layer 20b may be placed between the first wiring layer 20a and the second substrate 200. The second substrate 200 may be a silicon substrate or a silicon-on-insulator (SOI) substrate. For example, the second substrate 200 may include a silicon substrate, a germanium substrate, or a silicon-germanium substrate. The second substrate 200 may include first conductivity type impurities. For example, the first conductivity type impurities may include p-type impurities, such as one or more of aluminum (Al), boron (B), indium (In), and gallium (Ga).

A second gate electrode GEb may be provided on the third surface 200a of the second substrate 200. Second source/drain regions SDb may be provided on opposite sides of the second gate electrode GEb. For example, a source region may be provided on one side of the gate electrode GEb and a drain region may be provided on the other side of the gate electrode. The second source/drain regions SDb may be provided in the second substrate 200. The second source/drain regions SDb may be adjacent to the third surface 200a of the second substrate 200. For example, the second source/drain region SDb may have the second conductivity type (e.g., n-type) opposite to the first conductivity type of the second substrate 200. The second gate electrode GEb and the second source/drain regions SDb may constitute a source follower transistor SX discussed with reference to FIG. 1. For example, the second gate electrode GEb may be a source follower gate SF discussed with reference to FIG. 1. The second gate electrode GEb may be electrically connected to the floating diffusion region FD through the upper wiring line 211, the first bonding pad BP1, and a second bonding pad BP2 which will be discussed below.

A gate spacer GS may be provided on a sidewall of the second gate electrode GEb. A gate dielectric pattern GI may be interposed between the second gate electrode GEb and the second substrate 200.

The second wiring layer 20b may cover the third surface 200a of the second substrate 200. The second wiring layer 20b may include an intermediate dielectric layer 223, an intermediate contact 202, a second bonding pad BP2, and a contact pattern CP.

The intermediate dielectric layer 223 may cover the third surface 200a of the second substrate 200. The intermediate dielectric layer 223 may cover the second gate electrodes GEb. The intermediate dielectric layer 223 may include a non-conductive material. For example, the intermediate dielectric layer 223 may include a silicon-based dielectric material, such as one or more of silicon oxide, silicon nitride, and silicon oxynitride.

The second bonding pads BP2 may be provided in the intermediate dielectric layer 223. The second bonding pads BP2 may be provided in an upper portion of the intermediate dielectric layer 223. The intermediate contact 202 may be provided in the intermediate dielectric layer 223. The intermediate contact 202 may be connected to one of the second gate electrode GEb and the second source/drain region SDb. The intermediate contact 202 may be interposed between the second bonding pad BP2 and the second gate electrode GEb or between the second bonding pad BP2 and the second source/drain region SDb. For example, the second bonding pad BP2 may be connected through the intermediate contact 202 to one of the second gate electrode GEb and the second source/drain region SDb. A top surface of the second bonding pad BP2 may be exposed by the intermediate dielectric layer 223.

The second bonding pad BP2 may contact the first bonding pad BP1. The second bonding pad BP2 may be adjacent to the first wiring layer 20a, and the first bonding pad BP1 may be adjacent to the second wiring layer 20b. The first semiconductor chip SC1 and the second semiconductor chip SC2 may be electrically connected to each other through the first bonding pad BP1 and the second bonding pad BP2.

A connection contact TV may be provided to penetrate the second substrate 200. The connection contact TV may electrically connect the second semiconductor chip SC2 to a third semiconductor chip SC3 which will be discussed below.

The contact pattern CP may be interposed between the connection contact TV and the second bonding pad BP2. The contact pattern CP may lie between and electrically connect to each other the second bonding pad BP2 and the connection contact TV. The contact pattern CP may be provided in a lower portion of the intermediate dielectric layer 223.

The intermediate contact 202, the second bonding pad BP2, and the connection contact TV may include a metallic material. The intermediate contact 202, the second bonding pad BP2, and the connection contact TV may include at least one selected from tungsten (W), aluminum (Al), copper (Cu), tungsten nitride (WN), tantalum nitride (TaN), and titanium nitride (TiN). For example, the intermediate contact 202, the second bonding pad BP2, and the connection contact TV may each include copper.

A third semiconductor chip SC3 may be electrically connected to the second semiconductor chip SC2. The third semiconductor chip SC3 may be adjacent to the fourth surface 200b of the second substrate 200. The third semiconductor chip SC3 may include a third substrate 300 and a third wiring layer 20c.

The third substrate 300 may have a fifth surface 300a and a sixth surface 300b that are opposite to each other. The third wiring layer 20c may be provided on the fifth surface 300a of the third substrate 300. The third wiring layer 20c may be provided between the second substrate 200 and the third substrate 300. The third substrate 300 may be a silicon substrate or a silicon-on-insulator (SOI) substrate. For example, the third substrate 300 may include a silicon substrate, a germanium substrate, or a silicon-germanium substrate. The third substrate 300 may include first conductivity type impurities. For example, the first conductivity type impurities may include p-type impurities, such as one or more of aluminum (Al), boron (B), indium (In), and gallium (Ga).

A second device isolation pattern 105 may be provided in the third substrate 300. For example, the second device isolation pattern 105 may be provided in a seventh trench TR7. The seventh trench TR7 may be recessed from the fifth surface 300a of the third substrate 300. A bottom surface of the second device isolation pattern 105 may be provided in the third substrate 300. The second device isolation pattern 105 may have a structure the same as or similar to that of the first device isolation pattern 103. The second device isolation pattern 105 may have a width that gradually decreases in a direction from the fifth surface 300a toward the sixth surface 300b of the third substrate 300. The second device isolation pattern 105 may include a silicon-based dielectric material. For example, the second device isolation pattern 105 may include one or more of silicon nitride, silicon oxide, and silicon oxynitride. For another example, the second device isolation pattern 105 may include a plurality of layers, which layers may include different materials from each other.

A third gate electrode GEc may be provided on the fifth surface 300a of the third substrate 300. Third source/drain regions SDc may be provided on opposite sides of the third gate electrode GEc. The third source/drain regions SDc may be provided in the third substrate 300. The third source/drain regions SDc may be adjacent to the fifth surface 300a of the third substrate 300. For example, the third source/drain region SDc may have the second conductivity type (e.g., n-type) opposite to the first conductivity type of the third substrate 300. The third gate electrode GEc and the third source/drain regions SDc may constitute a logic transistor LT. The logic transistor LT may constitute logic circuits. The logic circuits may include, for example, a pixel array, a row decoder, a row driver, a column decoder, a timing generator, a correlated double sampler (CDS), an analog-to-digital converter (ADC), and an input/output (I/O) buffer.

A gate spacer GS may be provided on a sidewall of the third gate electrode GEc. A gate dielectric pattern GI may be interposed between the third gate electrode GEc and the third substrate 300.

The third wiring layer 20c may cover the fifth surface 300a of the third substrate 300. The third wiring layer 20c may include lower dielectric layers 224 and 225, a lower contact 203, lower wiring lines 212 and 213, and lower vias 217. The lower dielectric layers 224 and 225 may include a first lower dielectric layer 224 and a second lower dielectric layer 225. The first lower dielectric layer 224 may cover the fifth surface 300a of the third substrate 300. The first lower dielectric layer 224 may cover the third gate electrode GEc. The second lower dielectric layer 225 may be provided on the first lower dielectric layer 224. The first and second lower dielectric layers 224 and 225 may include a non-conductive material. For example, the first and second lower dielectric layers 224 and 225 may include a silicon-based dielectric material, such as one or more of silicon oxide, silicon nitride, and silicon oxynitride.

The lower wiring lines 212 and 213 may be provided in the second lower dielectric layer 225. The lower wiring lines 212 and 213 may include first lower wiring lines 212 and second lower wiring lines 213. The first lower wiring lines 212 may be provided in a lower portion of the second lower dielectric layer 225. The first lower wiring lines 212 may have their bottom surfaces exposed by the second lower dielectric layer 225. The second lower wiring lines 213 may be provided in an upper portion of the second lower dielectric layer 225. The second lower wiring lines 213 may have their top surfaces exposed by the second lower dielectric layer 225. The connection contact TV may lie between and electrically connect to each other the second lower wiring line 213 and the contact pattern CP.

The lower vias 217 may be provided in the second lower dielectric layer 225. The lower vias 217 may connect the first lower wiring lines 212 to the second lower wiring lines 213. The lower contact 203 may penetrate the first lower dielectric layer 224. The lower wiring lines 212 and 213 may be connected through the lower contact 203 to one of the third gate electrode GEc and the third source/drain region SDc.

An arrangement of the lower wiring lines 212 and 213 is not limited to that shown, but may be variously changed. The lower wiring lines 212 and 213, the lower vias 217, and the lower contacts 203 may include a metallic material. The lower wiring lines 212 and 213, the lower vias 217, and the lower contacts 203 may include at least one selected from tungsten (W), aluminum (Al), copper (Cu), tungsten nitride (W), tantalum nitride (TaN), and titanium nitride (TiN). For example, the lower wiring lines 212 and 213, the lower vias 217, and the lower contacts 203 may each include copper.

Referring back to FIG. 3, the image sensor may further include the logic chip 2000. The logic chip 2000 may be stacked below the sensor chip 1000.

On the optical black area OB, the first substrate 100 may be provided thereon with a first connection structure 50, a first pad terminal 81, and a bulk color filter 90. The first connection structure 50 may include a first light-shield pattern 51, a first dielectric pattern 53, and a first capping layer 55. The first light-shield pattern 51 may be provided on the second surface 100b of the first substrate 100. The first light-shield pattern 51 may cover inner sidewalls of third and fourth trenches TR3 and TR4. For example, the first light-shield pattern 51 may conform to the inner sidewalls of third and fourth trenches TR3 and TR4 and cover the inner sidewalls of third and fourth trenches TR3 and TR4. The first light-shield pattern 51 may penetrate the photoelectric conversion layer 10, the first wiring layer 20a, the second wiring layer 20b, and the second substrate 200, thereby being electrically connected to the photoelectric conversion layer 10 and the second wiring layer 20b. For example, the first light-shield pattern 51 may be in contact with wiring lines in the second wiring layer 20b and with the pixel isolation pattern 150 in the photoelectric conversion layer 10. Therefore, the first connection structure 50 may be electrically connected to wiring lines in the second wiring layer 20b. The first light-shield pattern 51 may block a light ray incident on the optical black area OB.

The first pad terminal 81 may be provided in the third trench TR3 to fill an unoccupied portion of the third trench TR3. The first pad terminal 81 may include a metallic material, such as aluminum. The first pad terminal 81 may be connected to the pixel isolation pattern 150, for example, to the second isolation pattern 153. Therefore, a negative voltage may be applied through the first pad terminal 81 to the pixel isolation pattern 150.

The first dielectric pattern 53 may be provided on the first light-shield pattern 51 to fill an unoccupied portion of the fourth trench TR4. The first dielectric pattern 53 may penetrate the photoelectric conversion layer 10, the first wiring layer 20a, the second wiring layer 20b, and the second substrate 200. The first capping layer 55 may be provided on the first dielectric pattern 53. The first capping layer 55 may include the same material as that of the capping pattern 155.

The bulk color filter 90 may be provided on the first pad terminal 81, the first light-shield pattern 51, and the first capping layer 55. The bulk color filter 90 may cover the first pad terminal 81, the first light-shield pattern 51, and the first capping layer 55. A first protection layer 71 may be provided on and cover the bulk color filter 90.

A photoelectric conversion region 110′ and a dummy region 111 may be provided on the optical black area OB of the first substrate 100. The photoelectric conversion region 110′ may be doped with impurities, for example, having the second conductivity type (e.g., n-type) different from the first conductivity type. The photoelectric conversion region 110′ may have a similar structure to that of the photoelectric conversion region 110 discussed in FIG. 5, but may not generate electrical signals from received light. The dummy region 111 may not be doped with impurities. The photoelectric conversion region 110′ and the dummy region 111 may generate signals that are used as information to remove subsequent process noise.

On the pad area PAD, the first substrate 100 may be provided thereon with a second connection structure 60, a second pad terminal 83, and a second protection layer 73. The second connection structure 60 may include a second light-shield pattern 61, a second dielectric pattern 63, and a second capping layer 65.

The second light-shield pattern 61 may be provided on the second surface 100b of the first substrate 100. For example, the second light-shield pattern 61 may conformally cover inner sidewalls of fifth and sixth trenches TR5 and TR6. The second light-shield pattern 61 may penetrate the photoelectric conversion layer 10, the first wiring layer 20a, the second wiring layer 20b, and the second substrate 200. For example, the second light-shield pattern 61 may be in contact with wiring lines in the third wiring layer 20c. The second light-shield pattern 61 may include a metallic material, such as tungsten.

The second pad terminal 83 may be provided in the fifth trench TR5. The second pad terminal 83 may be provided on the second light-shield pattern 61 to fill an unoccupied portion of the fifth trench TR5. The second pad terminal 83 may include a metallic material, such as aluminum. The second pad terminal 83 may serve as an electrical connection path between an image sensor device and an external device. The second dielectric pattern 63 may fill an unoccupied portion of the sixth trench TR6. The second dielectric pattern 63 may penetrate the photoelectric conversion layer 10, the first wiring layer 20a, the second wiring layer 20b, and the second substrate 200. The second capping layer 65 may be provided on the second dielectric pattern 63. The second capping layer 65 may include the same material as that of the capping pattern 155. The second protection layer 73 may cover the second capping layer 65 and a portion of the second light-shield pattern 61.

A current applied through the second pad terminal 83 may flow toward the pixel isolation pattern 150 through the second light-shield pattern 61, wiring lines in the second wiring layer 20b, and the first light-shield pattern 51. The photoelectric conversion regions 110 and 110′ and the dummy region 111 may generate electrical signals, and the electrical signals may be outwardly transmitted through the wiring lines in the second wiring layer 20b, wiring lines in the third wiring layer 20c, the second light-shield pattern 61, and the second pad terminal 83.

With reference to FIG. 6, the following will describe in detail the contact pattern CP and the connection contact TV.

Referring to FIG. 6, the contact pattern CP may be provided between the connection contact TV and the second bonding pad BP2. The connection contact TV may extend from the second lower wiring line 213 toward the contact pattern CP. The connection contact TV may be in contact with the contact pattern CP. For example, the connection contact TV may be in contact with a bottom surface of the contact pattern CP. The intermediate dielectric layer 223 may include an opening OP therein. The contact pattern CP may be conformally provided along an inner sidewall of the opening OP. That is, the intermediate dielectric layer 223 may have an opening OP, and the contact pattern CP may be provided in the opening OP. The opening OP may have a width that decreases in a direction toward the second substrate 200.

The second bonding pad BP2 may be electrically connected through the contact pattern CP to the connection contact TV, but may not be in direct contact with the connection contact TV. The second bonding pad BP2 may have a protrusion part PTP that is spaced apart vertically (e.g., in a third direction D3) from the connection contact TV by the contact pattern CP.

The contact pattern CP may include a recess region RSR that is recessed in a direction toward the second substrate 200 from a top surface of the contact pattern CP. The recess region RSR may have a width that decreases in a direction toward the second substrate 200.

The contact pattern CP may include a metallic material. For example, the contact pattern CP may include at least one selected from tungsten (W), aluminum (Al), copper (Cu), tungsten nitride (W), tantalum nitride (TaN), and titanium nitride (TiN). The contact pattern CP may include a metallic material different from that of the second bonding pad BP2. For example, the second bonding pad BP2 may include copper, and the contact pattern CP may include tungsten. For another example, the contact pattern CP may include the same material as that of the second bonding pad BP2.

The second bonding pad BP2 provided on the contact pattern CP may include a line part LIN and a protrusion part PTP. The line part LIN may be a segment that extends in the second direction D2 in an upper portion of the intermediate dielectric layer 223. The protrusion part PTP may be a segment that protrudes from the line part LIN toward the contact pattern CP. The protrusion part PTP may protrude toward the recess region RSR of the contact pattern CP. The protrusion part PTP may fill the recess region RSR. The top surface of the contact pattern CP may be in contact with a bottom surface of the line part LIN. A third width W3 may be given as a width of the protrusion part PTP. The third width W3 may decrease in a direction toward the second substrate 200.

A bottom surface of the contact pattern CP may be coplanar with a top surface of the second substrate 200. The bottom surface of the contact pattern CP may be located at a first level LV1. A top surface of the connection contact TV may be located at a second level LV2. A lowermost surface of the second bonding pad BP2 may be located at a third level LV3. The protrusion part PTP of the second bonding pad BP2 may have a bottom surface located at the third level LV3. For example, the second level LV2 may be higher than the first level LV1, and the third level LV3 may be higher than the second level LV2. The second level LV2 may be positioned between the first level LV1 and the third level LV3. The top surface and a portion of a sidewall of the connection contact TV may be in contact with the contact pattern CP. Alternatively, the first level LV1 and the second level LV2 may be the same as each other. For example, the top surface of the connection contact TV may be in contact with the bottom surface of the contact pattern CP.

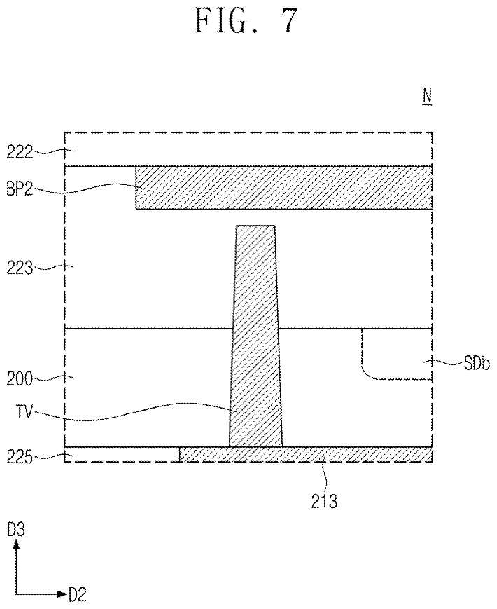

FIG. 7 illustrates an enlarged cross-sectional view of section N depicted in FIG. 5, showing an image sensor according to a comparative example. In the comparative example, a repetitive description of technical features repetitive to those discussed above with reference to FIGS. 4 to 6 will be omitted, and a difference thereof will be explained in detail.

Referring to FIG. 7, the contact pattern CP may be omitted which is discussed with reference to FIG. 6. The second bonding pad BP2 may not include the protrusion part PTP discussed with reference to FIG. 6. Therefore, a relatively large distance may be provided between the second bonding pad BP2 and the second lower wiring line 213. For example, the connection contact TV that penetrates the second substrate 200 and the intermediate dielectric layer 223 may be required to have a relatively large length so as to electrically connect the second bonding pad BP2 to the second lower wiring line 213. In this case, no contact hole may be formed deep sufficiently enough to form the connection contact TV, and thus the second bonding pad BP2 and the second lower wiring line 213 may not be electrically connected to each other. When the intermediate dielectric layer 223 is formed to have a small thickness to avoid the problem mentioned above, there may be an occurrence of failure due to contact between the second bonding pad BP2 and the second gate electrode GEb (see FIG. 5).

According to the disclosure, as illustrated in FIG. 6, the contact pattern CP may be provided in the intermediate dielectric layer 223. The contact pattern CP may be provided below and electrically connected to the second bonding pad BP2. As the contact pattern CP is provided in a lower portion of the intermediate dielectric layer 223, it may be possible to provide a relatively small length to the connection contact TV that electrically connects the second bonding pad BP2 to the second lower wiring line 213. In this case, it may be possible to solve the problem resulting from that no contact hole is formed deep sufficiently enough to form the connection contact TV, and that the second bonding pad BP2 and the second lower wiring line 213 are not electrically connected to each other. In addition, because it is not required that the intermediate dielectric layer 223 be formed to have a small thickness to avoid the problem, it may be possible to prevent the occurrence of failure due to contact between the second bonding pad BP2 and the second gate electrode GEb. As a result, the image sensor may increase in electrical properties.

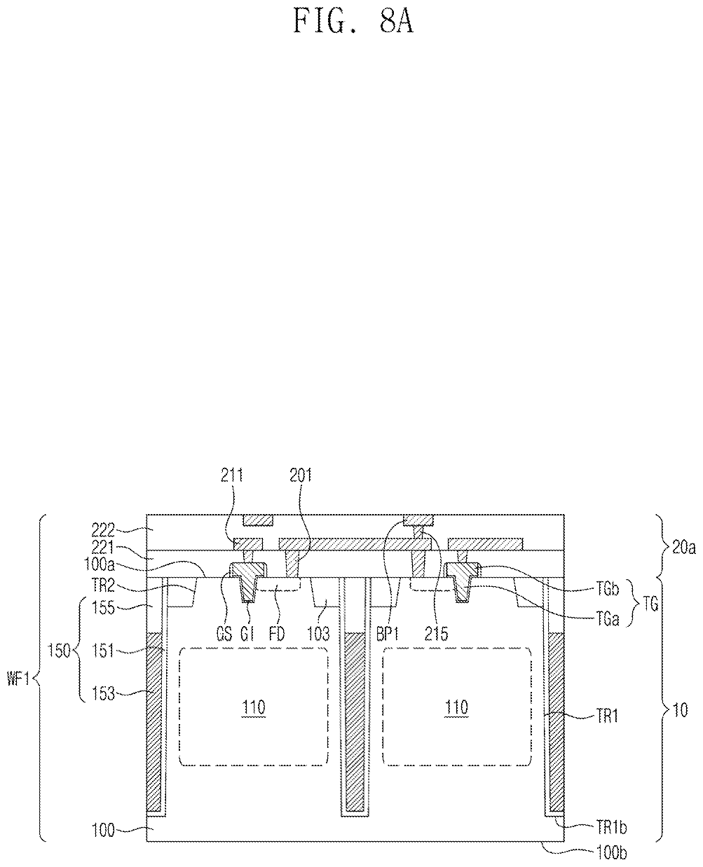

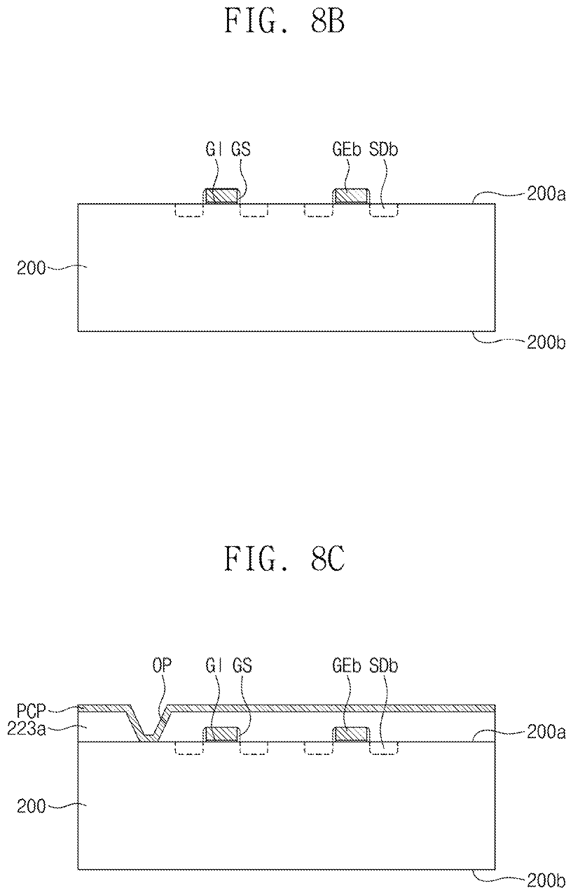

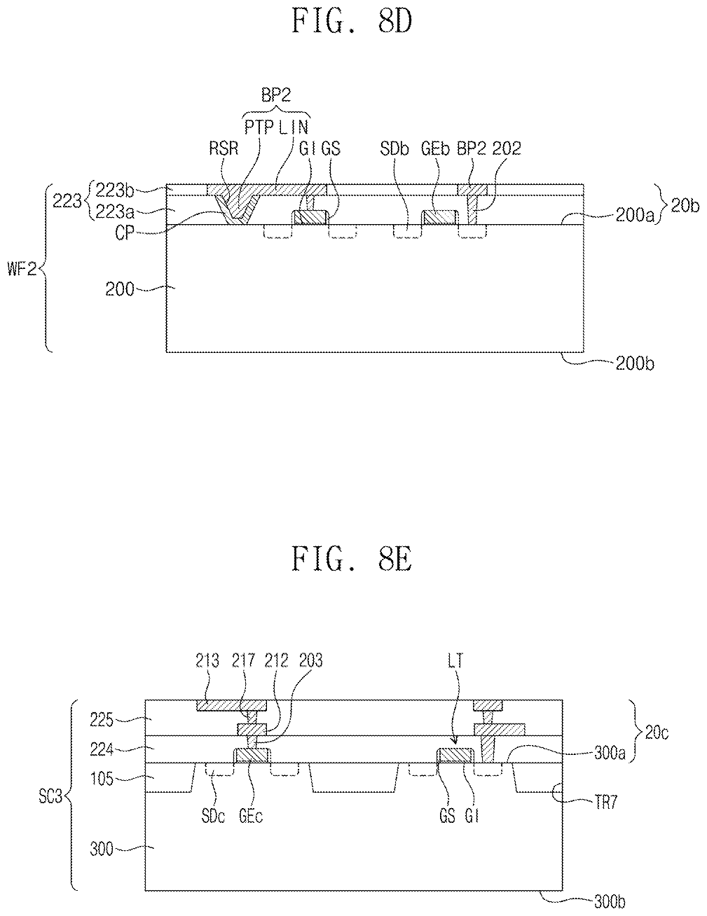

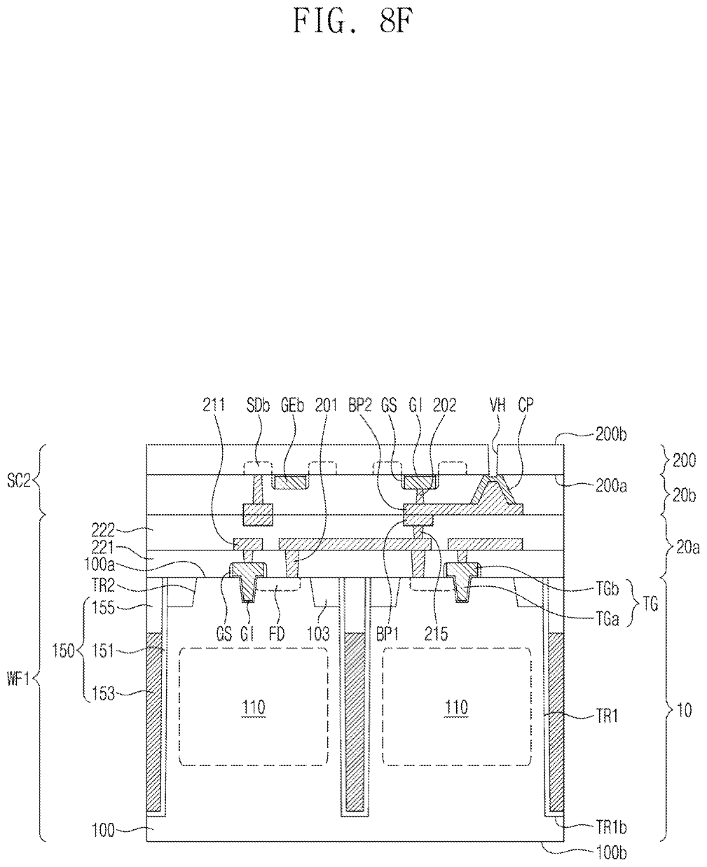

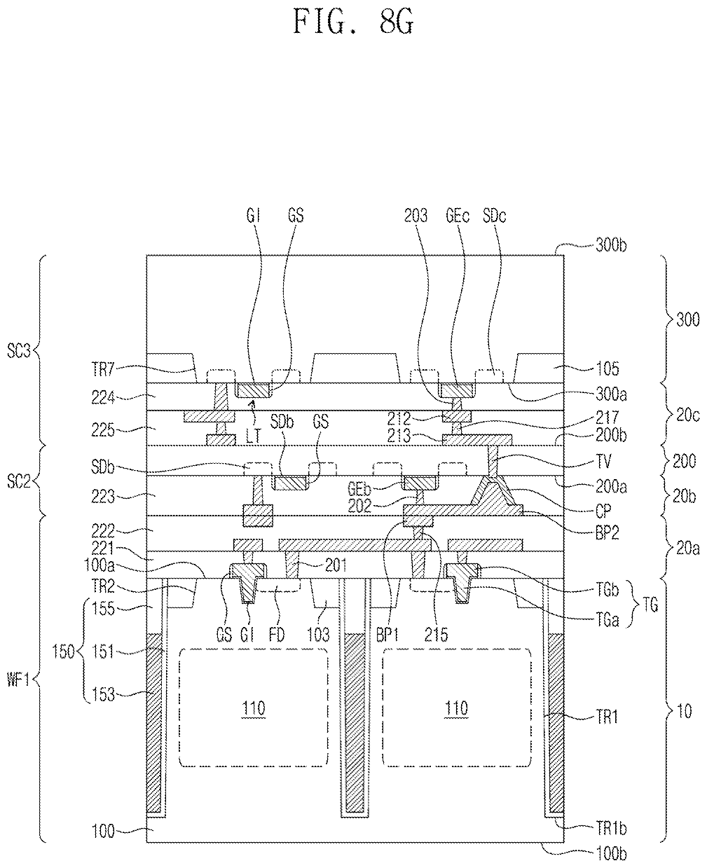

FIGS. 8A to 8G illustrate cross-sectional views showing a method of fabricating an image sensor according to an example embodiment of the disclosure.

Referring to FIG. 8A, a first substrate 100 may be prepared which has a first surface 100a and a second surface 100b that are opposite to each other. The first substrate 100 may include impurities having a first conductivity type (e.g., p-type). For example, the first substrate 100 may be a substrate in which an epitaxial layer having the first conductivity type is formed on a bulk silicon substrate having the first conductivity type. For another example, the first substrate 100 may be a bulk substrate which includes a well having the first conductivity type.

A second trench TR2 may be formed on the first surface 100a of the first substrate 100. A first device isolation pattern 103 may be formed in the second trench TR2. The first device isolation pattern 103 and the first substrate 100 may be etched to form a first trench TR1. A pixel isolation pattern 150 may be formed in the first trench TR1. The first trench TR1 may have a bottom surface TR1b located at a higher level than that of the second surface 100b of the first substrate 100.

The first substrate 100 may be doped with impurities to form photoelectric conversion regions 110. The photoelectric conversion regions 110 may have a second conductivity type (e.g., n-type) different from the first conductivity type (e.g., p-type).

A transfer gate TG may be formed on the first surface 100a of the first substrate 100. The transfer gate TG may include a second part TGb provided on the first surface 100a of the first substrate 100, and may also include a first part TGa that extend into the first substrate 100 from the second part TGb. According to an example embodiment, first gate electrodes GEa discussed with reference to FIG. 4 may be formed on the first surface 100a of the first substrate 100.

The first surface 100a of the first substrate 100 may be doped with impurities to form a floating diffusion region FD. The floating diffusion region FD may include impurities having the second conductivity type (e.g., n-type). According to an example embodiment, first source/drain regions SDa discussed with reference to FIG. 4 may be formed on opposite sides of the first gate electrode GEa.

A first upper dielectric layer 221 may be formed to cover the transfer gate TG. Upper contacts 201 may be formed in the first upper dielectric layer 221. Upper wiring lines 211 may be formed on the first upper dielectric layer 221. A second upper dielectric layer 222 may be formed on the first upper dielectric layer 221, covering the upper wiring lines 211. Upper vias 215 and first bonding pads BP1 may be formed in the second upper dielectric layer 222. The first bonding pads BP1 may have their top surfaces exposed by the second upper dielectric layer 222. Eventually, a first wafer part WF1 may be formed. The first wafer part WF1 may finally constitute a first semiconductor chip SC1 discussed with reference to FIG. 5.

Referring to FIG. 8B, a second substrate 200 may be prepared which has a third surface 200a and a fourth surface 200b that are opposite to each other. The second substrate 200 may include impurities having the first conductivity type (e.g., p-type). For example, the second substrate 200 may be a substrate in which an epitaxial layer having the first conductivity type is formed on a bulk silicon substrate having the first conductivity type. For another example, the second substrate 200 may be a bulk substrate which includes a well having the first conductivity type.

Second gate electrodes GEb may be formed on the third surface 200a of the second substrate 200. Second source/drain regions SDb may be formed on opposite sides of the second gate electrode GEb. The second gate electrode GEb and the second source/drain regions SDb may constitute the source follower transistor SX discussed with reference to FIG. 1.

Referring to FIG. 8C, a first intermediate dielectric layer 223a may be formed to cover the second gate electrodes GEb. An opening OP may be formed to penetrate the first intermediate dielectric layer 223a. The opening OP may expose the third surface 200a of the second substrate 200.

A preliminary contact pattern PCP may be conformally formed along a bottom surface and an inner sidewall of the opening OP and along a top surface of the first intermediate dielectric layer 223a. For example, the preliminary contact pattern PCP may include tungsten.

Referring to FIG. 8D, a planarization process may be performed on the preliminary contact pattern PCP. The planarization process may continue until the top surface of the first intermediate dielectric layer 223a is exposed. Accordingly, a contact pattern CP may be formed in the first intermediate dielectric layer 223a. The contact pattern CP may include a recess region RSR that is recessed toward the second substrate 200 from the top surface of the contact pattern CP. Intermediate contacts 202 may be formed in the first intermediate dielectric layer 223a.

Second bonding pads BP2 may be formed on the first intermediate dielectric layer 223a. The second bonding pad BP2 connected to the contact pattern CP may include a line part LIN and a protrusion part PTP that protrudes from the line part LIN toward the recess region RSR of the contact pattern CP. For example, the protrusion part PTP of the second bonding pad BP2 may fill the recess region RSR. A second intermediate dielectric layer 223b may be formed on the first intermediate dielectric layer 223a. The formation of the second intermediate dielectric layer 223b may include forming a dielectric layer on the first intermediate dielectric layer 223a and performing a planarization process until top surfaces of the second bonding pads BP2 are exposed. The first intermediate dielectric layer 223a and the second intermediate dielectric layer 223b may constitute an intermediate dielectric layer 223. As a result, a second wafer part WF2 may be formed. The second wafer part WF2 may finally constitute a second semiconductor chip SC2 discussed with reference to FIG. 5.

Referring to FIG. 8E, a third substrate 300 may be prepared which has a fifth surface 300a and a sixth surface 300b that are opposite to each other. The third substrate 300 may include impurities having the first conductivity type (e.g., p-type). For example, the third substrate 300 may be a substrate in which an epitaxial layer having the first conductivity type is formed on a bulk silicon substrate having the first conductivity type. For another example, the third substrate 300 may be a bulk substrate which includes a well having the first conductivity type.

A seventh trench TR7 may be formed on the fifth surface 300a of the third substrate 300. A second device isolation pattern 105 may be formed in the seventh trench TR7. Third gate electrodes GEc may be formed on the fifth surface 300a of the third substrate 300. Third source/drain regions SDc may be formed on opposite sides of the third gate electrode GEc. The third gate electrode GEc and the third source/drain regions SDc may constitute a logic transistor LT.

A first lower dielectric layer 224 may be formed to cover the third gate electrodes GEc. Lower contacts 203 may be formed in the first lower dielectric layer 224. First lower wiring lines 212 may be formed on the first lower dielectric layer 224. A second lower dielectric layer 225 covering the first lower wiring lines 212 may be formed on the first lower dielectric layer 224. Lower vias 217 and second lower wiring lines 213 may be formed in the second lower dielectric layer 225. A top surface of the second lower wiring line 213 may be exposed by the second lower dielectric layer 225. As a result, a third semiconductor chip SC3 may be formed.

Referring to FIG. 8F, the second wafer part WF2 may be flipped and attached to the first wafer part WF1. For example, the second wafer part WF2 may be flipped to cause the first bonding pad BP1 to contact the second bonding pad BP of the second wafer part WF2, and then a thermocompression process may be performed to bond the second wafer part WF2 to the first wafer part WF1.

A thinning process may be performed on the fourth surface 200b of the second substrate 200. Therefore, the second substrate 200 may have a reduced thickness. As a result, a second semiconductor chip SC2 may be formed. A contact hole VH may be formed to penetrate the second substrate 200. The contact hole VH may expose the top surface of the contact pattern CP.

According to the disclosure, because the contact pattern CP is formed, it may not be required that the contact hole VH be formed to have a relatively large depth. Therefore, the contact hole VH may not be formed deep, and thus it may be possible to prevent the occurrence of no electrical connection between the second lower wiring line 213 and the second bonding pad BP2.

Referring to FIG. 8G, a connection contact TV may be formed in the contact hole VH. Afterwards, the third semiconductor chip SC3 may be flipped and attached to the second semiconductor chip SC2. For example, the third semiconductor chip SC3 may be flipped to allow the connection contact TV and the second lower wiring line 213 to contact each other, and then a thermocompression process may be performed to bond the third semiconductor chip SC3 to the second semiconductor chip SC2.

Referring back to FIG. 5, a thinning process may be performed on the second surface 100b of the first substrate 100. The thinning process may expose bottom surfaces of the first and second isolation patterns 151 and 153. As a result, a first semiconductor chip SC1 may be formed. A first fixed charge layer 132, a second fixed charge layer 134, and a planarization layer 136 may be formed on the second surface 100b of the first substrate 100. A light-shield pattern 315 and a low-refractive pattern 311 may be formed on the planarization layer 136. A protection layer 316 may be formed to cover the low-refractive pattern 311. Color filters 303 may be formed on the protection layer 316. A microlens part 306 may be formed on the color filters 303.

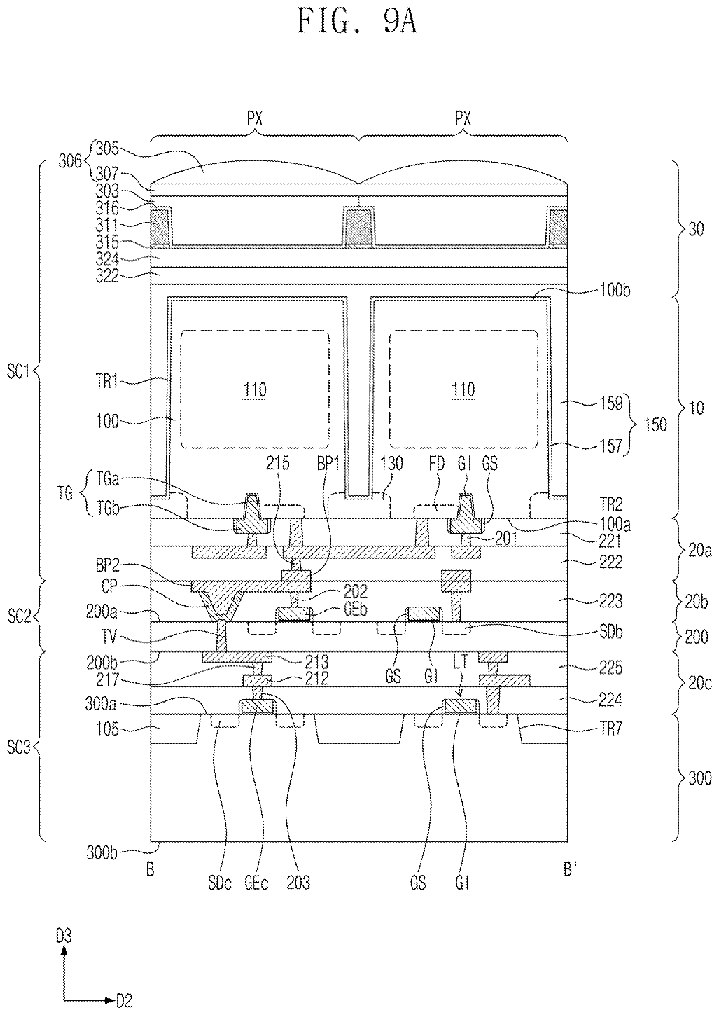

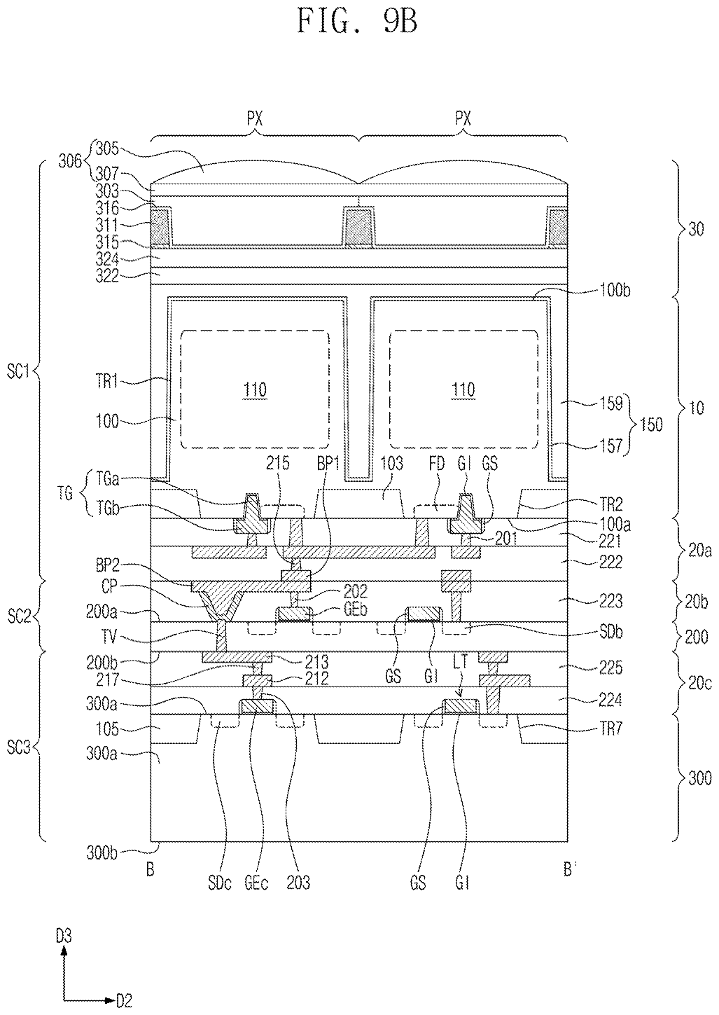

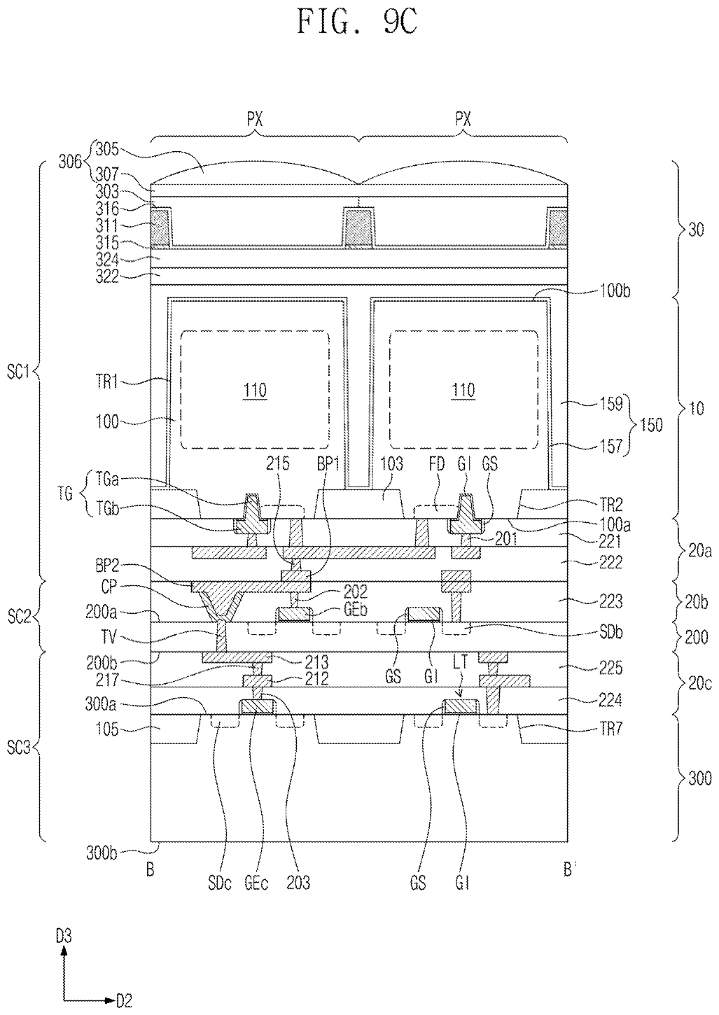

FIGS. 9A to 9C illustrate cross-sectional views taken along line B-B′ of FIG. 4, showing an image sensor according to an example embodiment of the disclosure. In the example embodiment that follows, a repetitive description of technical features repetitive to those discussed above with reference to FIGS. 4 to 6 will be omitted, and a difference thereof will be explained in detail.

Referring to FIG. 9A, the pixel isolation pattern 150 may be provided in the first trench TR1. The first trench TR1 may be recessed from the second surface 100b of the first substrate 100. The first trench TR1 may have a width that decreases in a direction from the second surface 100b toward the first surface 100a of the first substrate 100.

The pixel isolation pattern 150 may include a fixed charge layer 157 conformally provided along an inner wall of the first trench TR1 and a buried dielectric pattern 159 provided on the fixed charge layer 157. The fixed charge layer 157 may have a negative fixed charge. The fixed charge layer 157 may be formed of one of metal oxide and metal fluoride that include at least one metal selected from hafnium (Hf), zirconium (Zr), aluminum (Al), tantalum (Ta), titanium (Ti), yttrium (Y), and lanthanide. For example, the fixed charge layer 157 may be a hafnium oxide layer or an aluminum oxide layer. Hole accumulation may occur around the fixed charge layer 157. Therefore, dark current and white spot may be effectively reduced. The buried dielectric pattern 159 may include a dielectric material whose step coverage is excellent. For example, the buried dielectric pattern 159 may include a silicon oxide layer. The fixed charge layer 157 may extend onto the second surface 100b of the first substrate 100. The buried dielectric pattern 159 may also extend onto the second surface 100b of the first substrate 100.

A first passivation layer 322 and a second passivation layer 324 may be sequentially provided on a top surface of the buried dielectric pattern 159. Each of the first and second passivation layers 322 and 324 may include inorganic oxide. For example, each of the first and second passivation layers 322 and 324 may include silicon oxide.

A doped region 130 may be interposed between the pixel isolation pattern 150 and the first surface 100a of the first substrate 100. The doped region 130 may have the first conductivity type (e.g., p-type). The doped region 130 may surround a bottom surface of the pixel isolation pattern 150.

Referring to FIG. 9B, the pixel isolation pattern 150 may be substantially the same as the pixel isolation pattern 150 of FIG. 9A, but the first device isolation pattern 103 may be provided between the pixel isolation pattern 150 and the first surface 100a of the first substrate 100. The first device isolation pattern 103 and the pixel isolation pattern 150 may be vertically spaced apart from each other. For example, a portion of the first substrate 100 may extend between the first device isolation pattern 103 and the pixel isolation pattern 150.

Referring to FIG. 9C, the pixel isolation pattern 150 may be substantially the same as the pixel isolation pattern 150 of FIG. 9A, but the first device isolation pattern 103 may be in contact with the pixel isolation pattern 150. The first device isolation pattern 103 may be interposed between the pixel isolation pattern 150 and the first surface 100a of the first substrate 100.

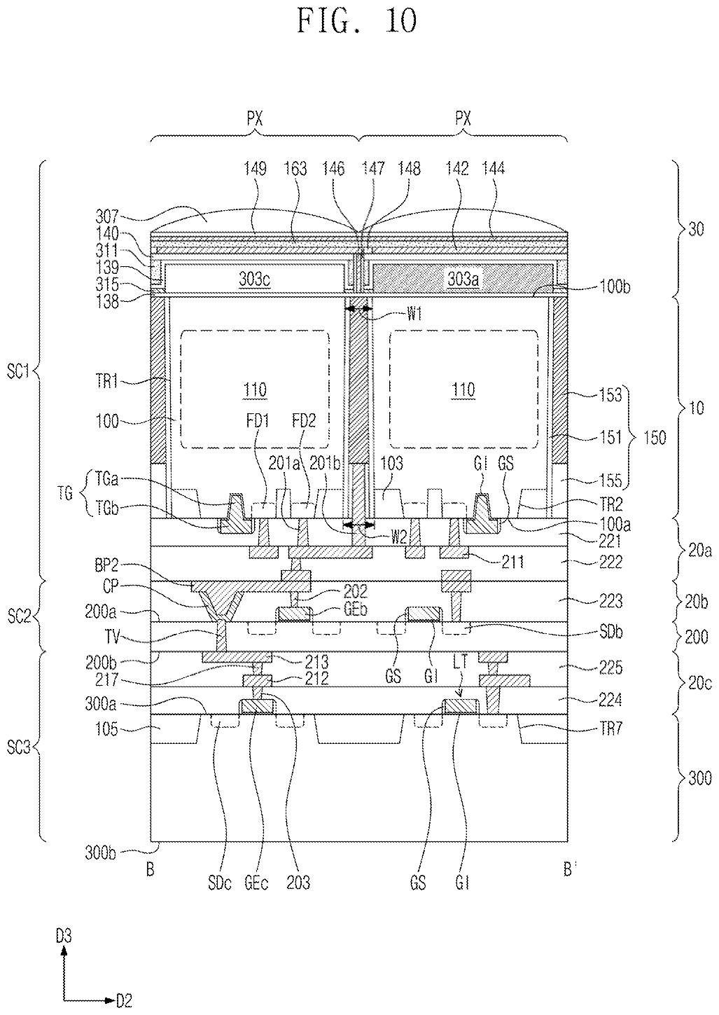

FIG. 10 illustrates a cross-sectional view taken along line B-B′ of FIG. 4, showing an image sensor according to an example embodiment of the disclosure.

Referring to FIG. 10, a first floating diffusion region FD1 and a second floating diffusion region FD2 may be provided adjacent to the first surface 100a of the first substrate 100. The first device isolation pattern 103 may separate the second floating diffusion region FD2 from the first floating diffusion region FD1.

A first dielectric layer 138 may be provided on the second surface 100b of the first substrate 100. Color filters 303a and 303c that correspond to the unit pixel regions PX may be provided on the first dielectric layer 138. A light-shield pattern 315 may be provided on the first dielectric layer 138 between the color filters 303a and 303c. A second dielectric layer 139 may cover lateral and top surfaces of the color filters 303a and 303c and a top surface of the light-shield pattern 315. A low-refractive pattern 311 may fill a space between the color filters 303a and 303c.

A third dielectric layer 140 may be provided on the second dielectric layer 139 and the low-refractive pattern 311. Pixel electrodes 142 that correspond to the unit pixel regions PX may be provide on the third dielectric layer 140. A dielectric pattern 148 may be interposed between the pixel electrodes 142. The dielectric pattern 148 may include, for example, a silicon oxide layer or a silicon nitride layer. A photoelectric conversion pattern 163 may be provided on the pixel electrodes 142. A common electrode 144 may be provided on the photoelectric conversion pattern 163. A passivation layer 149 may be provided on the common electrode 144. Microlenses 307 may be provided on the passivation layer 149.

The pixel electrode 142 and the common electrode 144 may include one or more of indium tin oxide (ITO), indium zinc oxide (IZO), zinc oxide (ZnO), and an organic transparent conductive material. The photoelectric conversion pattern 163 may be, for example, an organic photoelectric conversion layer. The photoelectric conversion pattern 163 may include a p-type organic semiconductor material and an n-type organic semiconductor material, which p-type and n-type organic semiconductor materials may form a p-n junction. Alternatively, the photoelectric conversion pattern 163 may include quantum dots or chalcogenide.

The pixel electrode 142 may be electrically connected through a via plug 146 to the pixel isolation pattern 150. For example, the pixel electrode 142 may be electrically connected to the second isolation pattern 153 of the pixel isolation pattern 150. The via plug 146 may penetrate the third dielectric layer 140, the low-refractive pattern 311, the second dielectric layer 139, the light-shield pattern 315, and the first dielectric layer 138, thereby being in contact with the pixel isolation pattern 150. A sidewall of the via plug 146 may be covered with a via dielectric layer 147. The pixel isolation pattern 150 may be electrically connected to the second floating diffusion region FD2 through an upper wiring line 211 and upper contacts 201a and 201b. A first upper contact 201a may be coupled to at least one selected from the transfer gate TG, the first floating diffusion region FD1, and the second floating diffusion region FD2. A second upper contact 201b may be coupled to the second isolation pattern 153. The second upper contact 201b may have a top surface located at a higher level than that of bottom surfaces of the first upper contacts 201a.

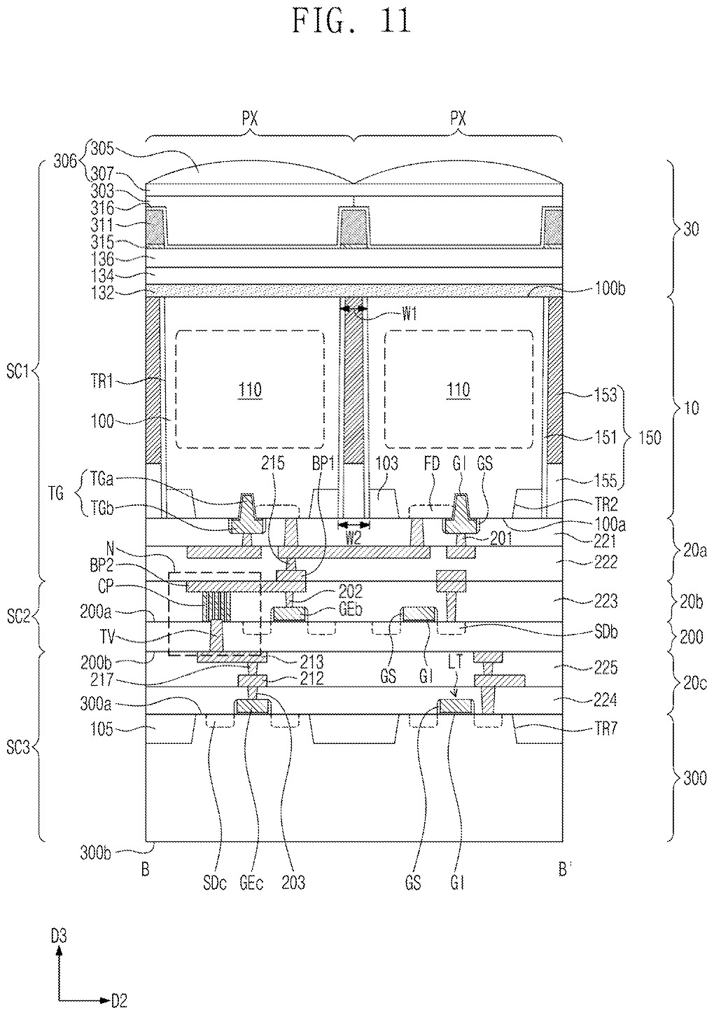

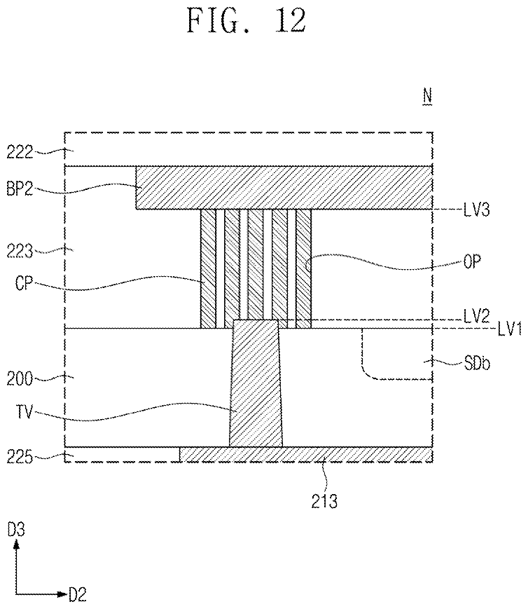

FIG. 11 illustrates a cross-sectional view taken along line B-B′ of FIG. 4, showing an image sensor according to an example embodiment of the disclosure. FIG. 12 illustrates an enlarged cross-sectional view showing section N depicted in FIG. 11. In the example embodiment that follows, a repetitive description of technical features repetitive to those discussed above with reference to FIGS. 4 to 6 will be omitted, and a difference thereof will be explained in detail.

Referring to FIGS. 11 and 12, the protrusion part PTP of the second bonding pad BP2 may be omitted which is discussed with reference to FIG. 6. A plurality of openings OP may be provided in the intermediate dielectric layer 223. A plurality of contact patterns CP may be provided to fill corresponding openings OP. The contact patterns CP may extend toward the second bonding pad BP2 from a bottom surface of the intermediate dielectric layer 223. The contact patterns CP may have their top surfaces in contact with a bottom surface of the second bonding pad BP2. The contact patterns CP may be provided spaced apart from each other in the second direction D2.

The connection contact TV may be electrically connected to the contact patterns CP. For example, the connection contact TV may be in contact with some of the contact patterns CP. Therefore, others of the contact patterns CP may not be in contact with the connection contact TV. The contact pattern CP in no contact with the connection contact TV may have a bottom surface in contact with the second substrate 200. According to another example embodiment, the connection contact TV may be in contact with all of the contact patterns CP. The connection contact TV may be in contact with a plurality of contact patterns CP.

The contact patterns CP may have their bottom surfaces coplanar with a top surface of the second substrate 200. The bottom surfaces of the contact patterns CP may be located at a first level LV1. The connection contact TV may have a top surface located at a second level LV2. The second bonding pad BP2 may have its bottom surface located at a third level LV3. For example, the second level LV2 may be higher than the first level LV1, and the third level LV3 may be higher than the second level LV2. The second level LV2 may be positioned between the first level LV1 and the third level LV3. The top surface and a portion of a sidewall of the connection contact TV may be in contact with the contact pattern CP. Alternatively, the first level LV1 and the second level LV2 may be the same as each other. For example, the top surface of the connection contact TV may be in contact with the bottom surface of the contact pattern CP.

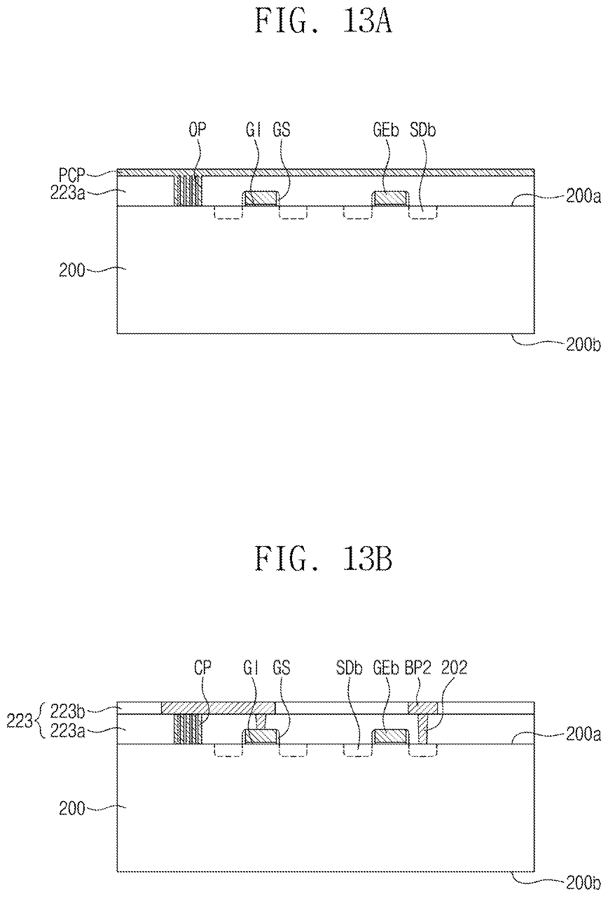

FIGS. 13A and 13B illustrate cross-sectional views showing a method of fabricating an image sensor according to an example embodiment of the disclosure.

Referring to FIG. 13A, after the process discussed with reference to FIG. 8B, a first intermediate dielectric layer 223a may be formed to cover the second gate electrodes GEb. An opening OP may be formed to penetrate the first intermediate dielectric layer 223a. The opening OP may expose the third surface 200a of the second substrate 200. For example, a plurality of openings OP may be provided. The openings OP may each have a width relatively less than that of the opening OP discussed with reference to FIG. 8C.

A preliminary contact pattern PCP may be conformally formed along a top surface of the first intermediate dielectric layer 223a. For example, the preliminary contact pattern PCP may include tungsten. The preliminary contact pattern PCP may completely fill the openings OP.

Referring to FIG. 13B, a planarization process may be performed on the preliminary contact pattern PCP. The planarization process may continue until the top surface of the first intermediate dielectric layer 223a is exposed. As a result, a plurality of contact patterns CP may be formed in the first intermediate dielectric layer 223a. Intermediate contacts 202 may be formed in the first intermediate dielectric layer 223a.

Second bonding pads BP2 may be formed on the first intermediate dielectric layer 223a. A second intermediate dielectric layer 223b may be formed on the first intermediate dielectric layer 223a. The formation of the second intermediate dielectric layer 223b may include forming a dielectric layer on the first intermediate dielectric layer 223a and performing a planarization process until top surfaces of the second bonding pads BP2 are exposed. The first intermediate dielectric layer 223a and the second intermediate dielectric layer 223b may constitute an intermediate dielectric layer 223. After that, there may be performed processes substantially the same as those discussed with reference to FIGS. 8A to 8G. In conclusion, an image sensor may be fabricated which is discussed with reference to FIGS. 11 and 12.

According to the disclosure, a contact pattern may be provided in an intermediate dielectric layer. The contact pattern may be provided below and electrically connected to a second bonding pad. As the contact pattern is provided in a lower portion of the intermediate dielectric layer, it may be possible to provide a relatively small length to a connection contact that electrically connects the second bonding pad to a second lower wiring line. In this case, it may be possible to solve failure resulting from that no contact hole is formed deep sufficiently enough to form the connection contact, and that the second bonding pad and the second lower wiring line are not electrically connected to each other.

In addition, because it is not required that the intermediate dielectric layer be formed to have a small thickness to avoid the problem, it may be possible to prevent the occurrence of failure due to contact between the second bonding pad and a second gate electrode. As a result, an image sensor may increase in electrical properties.

Although the disclosure have been described in connection with the an example embodiment of the disclosure illustrated in the accompanying drawings, it will be understood by one of ordinary skill in the art that variations in form and detail may be made therein without departing from the spirit and essential feature of the disclosure. The above disclosed embodiments should thus be considered illustrative and not restrictive.

What is claimed is:

1. An image sensor, comprising:
a first substrate comprising unit pixel regions, the first substrate having a first surface and a second surface on an opposite side of the first surface;
a second substrate provided below the first surface of the first substrate;
a third substrate provided below the second substrate;
a lower dielectric layer provided between the second substrate and the third substrate;
a lower wiring line provided in the lower dielectric layer;
an intermediate dielectric layer provided between the first substrate and the second substrate;
a first bonding pad provided in the intermediate dielectric layer;
a connection contact configured to penetrate the second substrate and electrically connect the lower wiring line to the first bonding pad; and
a contact pattern provided in the intermediate dielectric layer and below the first bonding pad,
wherein the first bonding pad is spaced apart from the connection contact by the contact pattern.

2. The image sensor of claim 1, further comprising:
an upper dielectric layer provided between the intermediate dielectric layer and the first surface of the first substrate; and
a second bonding pad provided in a lower portion of the upper dielectric layer,
wherein the first bonding pad and the second bonding pad are in contact with each other.

3. The image sensor of claim 1, further comprising a logic transistor provided in the third substrate,
wherein the lower dielectric layer covers the logic transistor.

4. The image sensor of claim 1, further comprising:
a source follower transistor provided in the second substrate; and
a floating diffusion region provided adjacent to the first surface of the first substrate,
wherein the source follower transistor is electrically connected through the first bonding pad to the floating diffusion region.

5. The image sensor of claim 1, further comprising a pixel isolation pattern provided in the first substrate, the pixel isolation pattern defining the unit pixel regions,
wherein a width of the pixel isolation pattern increases in a direction from the first surface toward the second surface.

6. The image sensor of claim 1, wherein the contact pattern comprises a first material and the first bonding pad comprises a second material different from the first material.

7. The image sensor of claim 1, wherein a top surface of the connection contact is at a first level higher than a second level of a bottom surface of the contact pattern.

8. The image sensor of claim 1, wherein the contact pattern comprises a recess region that is recessed in a direction from a top surface of the contact pattern toward the second substrate.

9. The image sensor of claim 8, wherein the first bonding pad comprises:
a line part that extends in a first direction; and
a protrusion part that protrudes from the line part toward the recess region of the contact pattern,
wherein a width of the protrusion part decreases in the direction toward the second substrate.

10. The image sensor of claim 1, wherein
the contact pattern comprises a plurality of contact patterns, and
the connection contact is in contact with one or more of the plurality of contact patterns.

11. An image sensor, comprising:
a first substrate comprising unit pixel regions;
a second substrate provided below the first substrate;
a third substrate provided below the second substrate;
a first wiring layer and a second wiring layer provided between the first substrate and the second substrate, the first wiring layer being closer than the second wiring layer to the first substrate;
a third wiring layer provided between the second substrate and third substrate; and
a connection contact configured to penetrate the second substrate and electrically connect the second wiring layer to the third wiring layer,
wherein the second wiring layer comprises:
a first bonding pad provided adjacent to the first wiring layer; and
a contact pattern provided between the first bonding pad and the connection contact,
wherein the contact pattern comprises a recess region that is recessed in a direction toward the second substrate from a top surface of the contact pattern,
wherein the first bonding pad comprises:
a line part that extends in a first direction; and
a protrusion part that protrudes from the line part into the recess region of the contact pattern in the direction toward the second substrate.

12. The image sensor of claim 11, wherein a width of the protrusion part of the first bonding pad decreases in the direction toward the second substrate.

13. The image sensor of claim 11, wherein a top surface of the contact pattern is in contact with a bottom surface of the line part of the first bonding pad.

14. The image sensor of claim 11, wherein the first wiring layer comprises a second bonding pad in contact with the first bonding pad.

15. The image sensor of claim 14, wherein the first substrate comprises a floating diffusion region,
wherein the floating diffusion region is electrically connected to the second bonding pad.

16. An image sensor, comprising:
a first substrate having a first surface and a second surface on an opposite side of the first surface;
a pixel isolation pattern provided in the first substrate, the pixel isolation pattern defining unit pixel regions, and the pixel isolation pattern comprising a first isolation pattern and a second isolation pattern that is between the first isolation pattern and the first substrate;
a photoelectric conversion region provided in each of the unit pixel regions;
a floating diffusion region provided in each of the unit pixel regions and adjacent to the first surface of the first substrate;
a transfer gate provided on the first surface of the first substrate;
a first wiring layer configured to cover the transfer gate, the first wiring layer comprising an upper dielectric layer, an upper wiring line provided in the upper dielectric layer, and a first bonding pad provided in the upper dielectric layer;
a second substrate provided below the first wiring layer;
a gate electrode provided on the second substrate;
a source region provided in the second substrate on a first side of the gate electrode and a drain region provided in the second substrate on a second side of the gate electrode;
a second wiring layer provided between the second substrate and the first wiring layer, the second wiring layer comprising an intermediate dielectric layer and a second bonding pad in the intermediate dielectric layer, the second bonding pad being in contact with the first bonding pad;
a third substrate provided below the second substrate;
a logic transistor provided on the third substrate;
a third wiring layer provided between the second substrate and the third substrate, the third wiring layer comprising a lower dielectric layer and a lower wiring line in the lower dielectric layer;
a connection contact configured to penetrate the second substrate and electrically connects the lower wiring line to the second bonding pad;
a contact pattern provided in the intermediate dielectric layer and between the second bonding pad and the connection contact;
a color filter provided on the second surface of the first substrate; and
a microlens part provided on the color filter,
wherein the first bonding pad is spaced apart from the connection contact by the contact pattern.

17. The image sensor of claim 16, wherein
the second bonding pad comprises copper, and
the contact pattern comprises tungsten.

18. The image sensor of claim 16, wherein the floating diffusion region is electrically connected to the gate electrode through the upper wiring line, the first bonding pad, and the second bonding pad.

19. The image sensor of claim 16, wherein
the contact pattern comprises a plurality of contact patterns that are spaced apart from each other in a first direction, and
the connection contact is in contact with some of the plurality of contact patterns.

20. The image sensor of claim 16, wherein the contact pattern comprises a recess region that is recessed in a direction toward the second substrate from a top surface of the contact pattern,
wherein the second bonding pad comprises:
a line part that extends in a first direction; and
a protrusion part that protrudes from the line part toward the recess region of the contact pattern.
